(19) United States
(12) Patent Application Publication
(10) Pub. No.: US 2010/0301436 A1
(43) Pub. Date: Dec. 2, 2010

(54) SEMICONDUCTOR DEVICE AND METHOD FOR MAKING SEMICONDUCTOR DEVICE

(75) Inventor: Naoya Sashida, Yokohama (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU SEMICONDUCTOR LIMITED, Yokohama-shi (JP)

(21) Appl. No.: 12/785,877

(22) Filed: May 24, 2010

(30) Foreign Application Priority Data
May 26, 2009 (JP) 2009-126811

(51) Int. Cl. H01L 23/48; H01L 29/92; H01L 29/82; H01L 21/768

(52) U.S. Cl. 257/421; 257/751; 257/532; 438/653; 257/E23.011; 257/E29.342; 257/E29.323; 257/E21.584

(57) ABSTRACT

A semiconductor device with a functional element including an upper electrode composed of an electrically conductive metal oxide and being configured to store information; an interlayer insulating film covering the functional element; a contact hole formed in the interlayer insulating film, the contact hole including a side wall surface and a bottom and exposing an upper surface of the upper electrode at the bottom; an electrically conductive barrier film covering the bottom and the side wall surface of the contact hole; and a tungsten film formed on the electrically conductive barrier film, the tungsten film filling at least part of the contact hole, wherein a layer in which silicon atoms are concentrated is formed at the interface between the tungsten film and the electrically conductive barrier film.

### CROSS-REFERENCE TO RELATED APPLICATIONS

This application is based upon and claims the benefit of priority of the prior Japanese Patent Application No. 2009-126811, filed on May 26, 2009 the entire contents of which are incorporated herein by reference.

### FIELD

The present invention relates to a semiconductor device including a readily reducible structure, such as an electrically conductive oxide film, and a method for making a semiconductor device.

### BACKGROUND

With the advancement of digital technologies, the need for high-speed processing a large-volume data has increased unprecedentedly in recent years. New memory devices are being proposed to meet this need.

For example, dynamic random access memories (DRAMs) have been widely used as high-speed semiconductor memories. Now attempts are being made to use metal oxides, which form high-dielectric-constant elements or ferroelectric elements, in memory capacitors instead of existing silicon oxide films or silicon nitride films. This is to comply with the decrease in capacitor area resulting from size reduction.

In recent years, nonvolatile, high-speed semiconductor memories that include ferroelectric capacitors using ferroelectric films as capacitor insulating films have been put to practical use. Such memories are called ferroelectric random access memories (FeRAMs). FeRAMs are voltage-driven devices that store information by utilizing hysteresis characteristics of ferroelectric films. Unlike flash memories, FeRAMs do not need injection of charges into floating gates and operate at high speed and low power consumption.

Ferroelectric films that have been used in FeRAMs heretofore include films composed of perovskite-type metal oxides, such as lead zirconate titanate (PZT), formed by a sol-gel method, a sputtering method, or a metalorganic chemical vapor deposition method (MOCVD method), and films composed of bismuth layered compounds such as SrBi₂Ta₂O₉ (SBT; Y1), SrBi₂(Na,Nb)₂O₉ (SBTN; YZ), Bi₄Ti₃O₉, (Bi,La)₄Ti₃O₁₂, and BiFeO₃.

Presently, studies are being conducted on magnetic random access memories (MRAMs) that use magnetic tunneling junctions (MTJs) for storing information.

According to conventional semiconductor devices that include ferroelectric films, metal oxide films that constitute the ferroelectric films may become readily reduced by hydrogen and lose the expected hysteresis characteristics. In order to avoid this problem, special care must be taken in forming upper electrodes after forming the ferroelectric films. After forming ferroelectric capacitors, it is essential to conduct a heat treatment in an oxygen atmosphere to compensate for the oxygen deficiencies in the ferroelectric films; however, when a noble metal stable in oxidative atmosphere such as platinum (Pt) is used in the upper electrodes, hydrogen, which is used to bury the ferroelectric capacitors with interlayer insulating films and to form wiring in the later process, may be activated by a catalytic effect of the noble metal such as platinum and may reduce the ferroelectric films.

For this reason, electrically conductive oxides such as iridium oxide (IrO₂) and ruthenium oxide (RuO₂) that are stable for processes conducted in oxidative atmosphere and generate no such catalytic effect have been used in the upper electrodes of ferroelectric capacitors. In order to block penetration of a hydrogen atmosphere and improve the interface characteristics between the ferroelectric films (PZT films) and upper electrodes, Japanese Patent No. 3661850 proposes that the upper electrode have a two-layer structure in which an iridium oxide film having a nonstoichiometric composition IrOₓ (x<2) as well as including oxygen deficiencies is used in the lower layer portion and an iridium oxide film having a higher degree of oxidation and a stoichiometric composition or a composition close to the stoichiometric, IrO₂, is used in the upper layer portion. However, electrically conductive oxide films such as iridium oxide films also become readily reduced once exposed to a hydrogen atmosphere and it is difficult to control the degree of oxidation to a desired level.

In sum, it is desirable for semiconductor devices including ferroelectric capacitors not to expose the ferroelectric films forming the ferroelectric capacitors and the electrically conductive oxide films forming the upper electrodes to a hydrogen atmosphere after the ferroelectric capacitors are formed.

In recent years, a stringent requirement for size reduction has also been imposed upon FeRAMs including the ferroelectric capacitors. Desirably, the diameter of contact holes formed in the interlayer insulating films should be reduced to correspond with the upper electrodes of the ferroelectric capacitors, and the aspect ratio (or b/a ratio) of the contact holes should be increased.

It has been common practice to fill such fine contact holes with tungsten (W) plugs formed by a CVD process. In this tungsten CVD process, it is common practice to reduce the tungsten source gas with hydrogen to achieve a high step coverage. However, when hydrogen is used, the electrically conductive oxides forming the upper electrodes and the ferroelectric films are reduced by hydrogen and the electrical characteristics of the ferroelectric capacitors deteriorate significantly during formation of the tungsten plugs. In order to avoid this problem, Japanese Laid-open Patent Publication No. Hei03-003332 describes a technique of forming tungsten plugs by reducing a source gas composed of tungsten hexafluoride (WF₆) with a silane (SiH₄) gas.

### SUMMARY

According to one aspect of the invention, a semiconductor device includes a functional element including an upper electrode composed of an electrically conductive metal oxide and being configured to store information; an interlayer insulating film covering the functional element; a contact hole formed in the interlayer insulating film, the contact hole including a side wall surface and a bottom and exposing the upper electrode at the bottom; an electrically conductive barrier film covering the bottom and the side wall surface of the contact hole; and a tungsten film formed on the electrically conductive barrier film, the tungsten film filling at least part of the contact hole, wherein a layer in which silicon atoms are concentrated is formed at the interface between the tungsten film and the electrically conductive barrier film.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIGS. 1A to 1E are diagrams illustrating a method for forming tungsten plugs according to a first embodiment.

FIG. 2 is a graph indicating the duration of an initialization process using silane and the step coverage achieved by an initial tungsten layer.

FIG. 3 is a graph indicating an example of a recipe used in the first embodiment.

FIG. 4 is a graph indicating a recipe which is a modification of the recipe of FIG. 3.

FIGS. 5A to 5K are diagrams illustrating steps of making a FeRAM according to a second embodiment.

FIG. 6 is a diagram illustrating an example of a barrier metal having a two-layer structure.

FIGS. 7A to 7W are diagrams illustrating steps of making a MRAM according to the second embodiment.

FIG. 8 is a diagram illustrating a layer structure of a MRAM device.

### DETAILED DESCRIPTION OF THE EMBODIMENTS

Regarding the technique of forming tungsten plugs by reducing a source gas composed of tungsten hexafluoride (WF₆) with a silane (SiH₄) gas, the inventors of the present invention have noticed two tendencies: (1) When the WF₆ source gas is reduced with a hydrogen gas, deposition of tungsten mainly occurs at the interfaces of the contact holes and thus a relatively high step coverage is achieved whereas when the WF₆ source gas is reduced with a silane gas, the reduction reaction occurs in a vapor phase, resulting in formation of tungsten particles which creep into contact holes and thereby cause failures; (2) The WF₆ molecules that have reached the contact holes become decomposed starting from inhomogeneous portions on the contact hole surfaces and form precipitates of tungsten, thereby tending to form tungsten overhangs at contact hole openings and degrading the step coverage. In addition to the problem of particle generation described above, tungsten may not sufficiently fill the contact holes. Embodiments effective for addressing these challenges are described below.

### First Embodiment

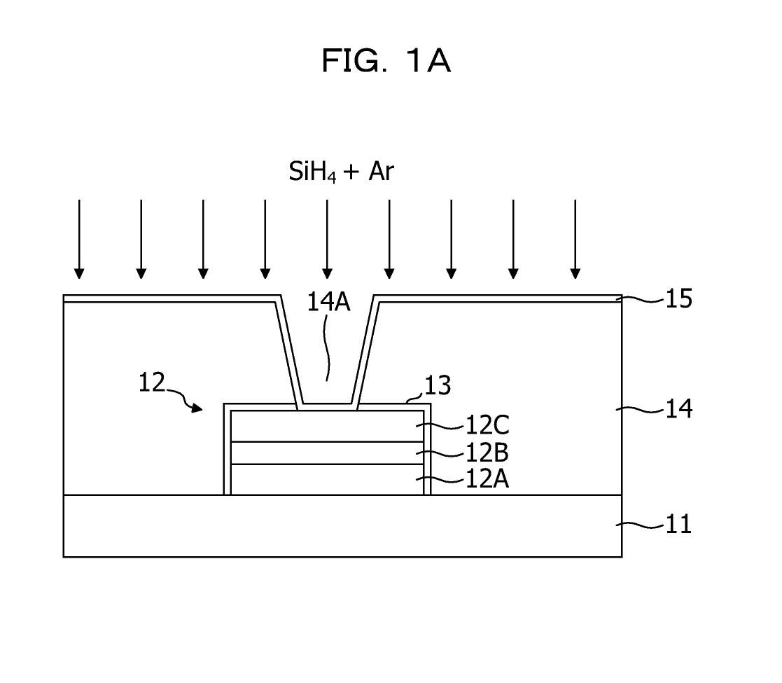

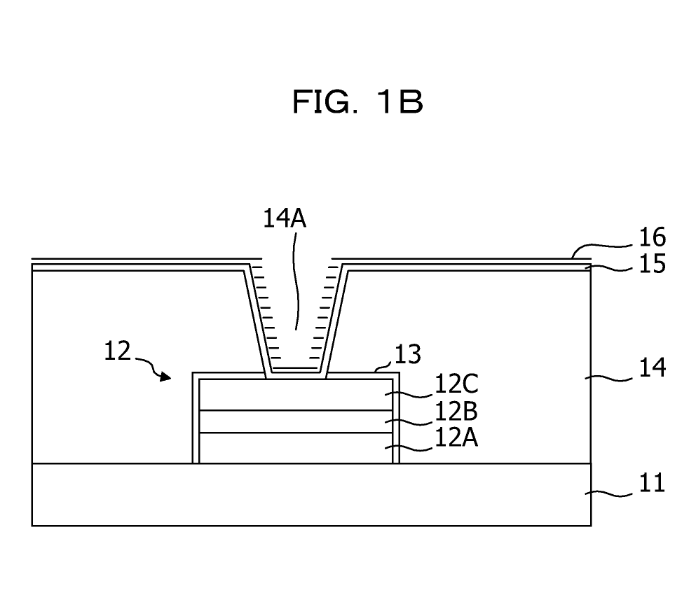

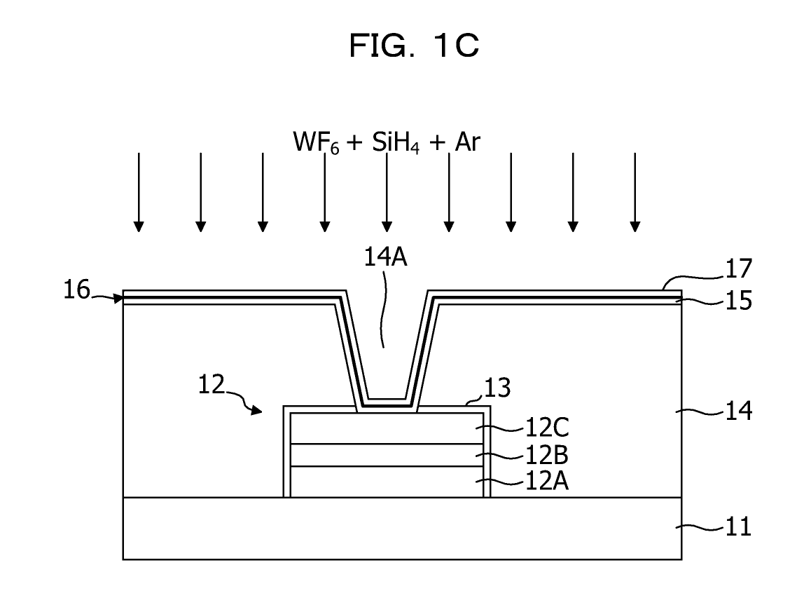

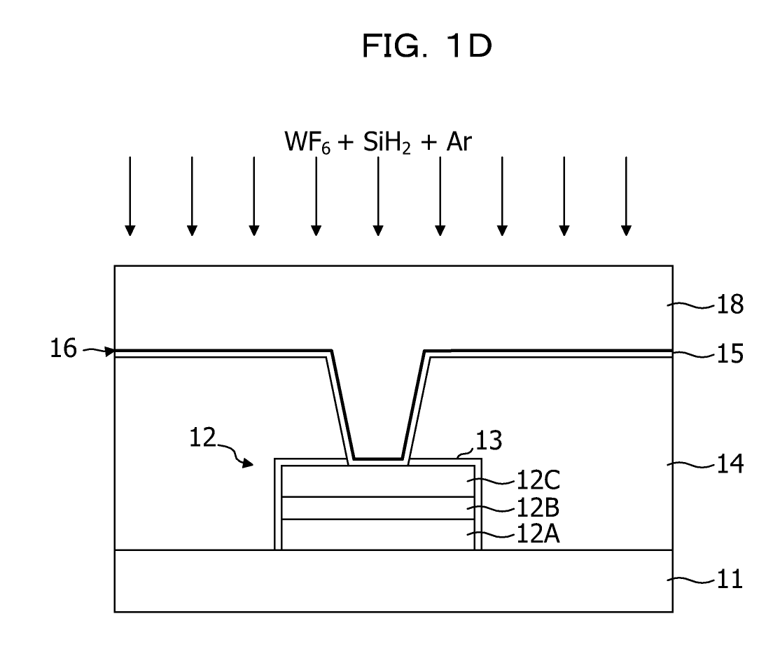

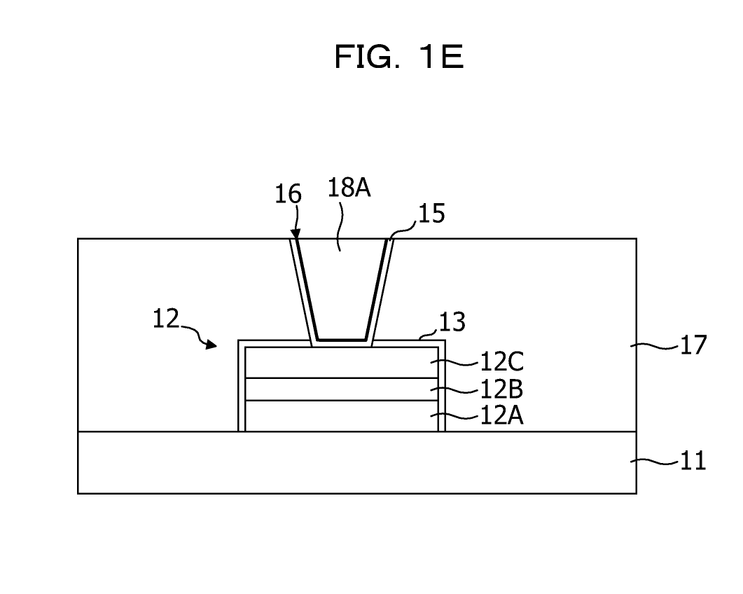

FIGS. 1A to 1D are diagrams illustrating a method for forming a tungsten plug according to a first embodiment.

Referring to FIG. 1A, a capacitor structure 12 is disposed on an insulating film 11 formed of a thermal oxide film or a CVD oxide film. The capacitor structure 12 includes a lower electrode 12A composed of platinum (Pt) or the like, a ferroelectric film 12B composed of lead zirconate titanate (PZT) or the like, and an upper electrode 12C composed of an electrically conductive oxide, such as iridium oxide (IrOₓ) that are sequentially stacked. The capacitor structure 12 is covered with a hydrogen barrier film 13 composed of aluminum oxide (Al₂O₃) or the like. The ferroelectric film 12B is typically formed by a sputtering method but may be formed by a sol-gel method or a metalorganic chemical vapor deposition method (MOCVD method). The lower electrode 12A and the upper electrode 12C are typically formed by a sputtering method. The hydrogen barrier film 13 may be formed by a MOCVD method.

The capacitor structure 12 is also covered with an interlayer insulating film 14, such as a tetraethoxysilane (TEOS) oxide film, having a low water content. A contact hole 14A that exposes the upper electrode 12C of the capacitor structure 12 is formed in the interlayer insulating film 14.

In the state illustrated in FIG. 1A, a barrier metal film 15 is formed on the interlayer insulating film 14 by a sputtering method. The barrier metal film 15 is an electrically conductive barrier film that is typically composed of an electrically conductive nitride such as TiN or TaN, and covers the side wall surface and the bottom surface of the contact hole 14A.

The structure illustrated in FIG. 1A is exposed to a silane (SiH₄) gas carried by an inert carrier gas such as an argon (Ar) gas. As a result, as illustrated in FIG. 1B, silicon (Si) atoms adsorb onto the surface of the barrier metal film 15 to form a silicon-rich layer 16. Hereinafter, the step of exposing the contact hole surface to the silane gas illustrated in FIG. 1A is referred to as an “initialization step”. For example, the silane gas is supplied at a flow rate of 10 sccm to 30 sccm and preferably 18 sccm along with an argon carrier gas at a flow rate of 500 sccm to 1000 sccm and preferably 2700 sccm and a nitrogen gas at a flow rate of 100 sccm to 1000 sccm and preferably 600 sccm. The initialization step is typically performed for 2 seconds or more, preferably 53 seconds or more, and more preferably 100 seconds or more, under a pressure of 1 Torr (133 Pa) to 80 Torr (10.6 kPa) and preferably 2.7 kPa at a substrate temperature of 300° C. to 470° C. and preferably 410° C. The duration of the initialization step is preferably 200 seconds or less to prevent a decrease in throughput of the semiconductor device production.

The thickness of the silicon-rich layer 16 thus formed increases by extending the duration of the initialization step illustrated in FIG. 1A but is generally a monoatomic layer thickness or more and 1 nm or less. The silicon atoms adhering on the surface of the barrier metal film 15 move about the surface of the barrier metal film 15 and are preferentially captured by defect-bearing portions, such as growth lines. For example, in the initialization step illustrated in FIG. 1A, when the silane gas is fed at a flow rate of 18 sccm along with the argon gas at a flow of 400 sccm for 53 seconds under a pressure of 2.7 kPa at a substrate temperature of 410° C., the silicon-rich layer 16 has a thickness of about 0.3 nm.

In the initialization step illustrated in FIG. 1A, since a hydrogen gas is not used as a carrier gas during feeding of the silane gas, there is no risk of hydrogen penetrating into the capacitor structure 12 through defects such as growth lines of the barrier metal film 15. Although 2 moles of hydrogen gas is generated as a result of decomposition of 1 mole of silane gas, the flow rate of the silane gas is low as described above and thus the reduction of the upper electrode 12C or the ferroelectric film 12B by the hydrogen gas is suppressed to a minimum level. The electrical characteristics of the capacitor structure 12 are not substantially deteriorated.

The silicon-rich layer 16 formed in the initialization step does not have to be a continuous silicon film and may be a non-continuous film constituted by silicon atoms concentrating in defect portions of the barrier metal film 15.

Next, as illustrated in FIG. 1C, tungsten hexafluoride (WF₆) serving as the tungsten source gas is fed over the structure illustrated in FIG. 1B along with a silane gas serving as a reductant and a carrier gas containing an inert gas such as argon to form an initial tungsten film 17 having a thickness of 10 nm to 30 nm, for example, on the barrier metal film 15. For example, the step illustrated in FIG. 1C is performed by supplying the WF₆ gas at a flow rate of 5 sccm to 30 sccm and preferably 15 sccm along with a silane gas at a flow rate of 1 sccm to 10 sccm and preferably 4 sccm, an argon carrier gas at a flow rate of 500 sccm to 1000 sccm and preferably 800 sccm, and a nitrogen gas at a flow rate of 100 sccm to 1000 sccm and preferably 600 sccm for 30 seconds under a pressure of 133 Pa to 10.6 kPa and preferably 2.7 kPa at a substrate temperature of 300° C. to 470° C. and preferably 410° C. In general, reduction of WF₆ with silane tends to be a vapor phase reaction that generates particles and thus the quality of the initial tungsten film 17 tends to be low. However, in this embodiment, the silicon-rich layer 16 is already formed on the barrier metal film 15 in the initialization step illustrated in FIG. 1B. Deposition of tungsten thus preferentially occurs on the barrier metal film 15 and the deterioration of the quality of the initial tungsten film 17 is suppressed to a minimum level. Since hydrogen is not used in reducing the tungsten raw material in the step illustrated in FIG. 1C, the reduction of the upper electrode 12C and the ferroelectric film 12B by hydrogen is suppressed to a minimum level.

After the step illustrated in FIG. 1C, tungsten hexafluoride (WF₆) serving as the tungsten source gas and a hydrogen gas serving as a reductant are fed over the structure illustrated in FIG. 1C to form a tungsten burying layer 18 on the barrier metal film 15 and fill the contact hole 14A with the tungsten burying layer 18 as illustrated in FIG. 1D.

For example, the step illustrated in FIG. 1D is performed by feeding a WF₆ gas at a flow rate of 30 sccm to 200 sccm and preferably 90 sccm, a hydrogen gas at a flow rate of 500 sccm to 2000 sccm and preferably 750 sccm, an argon carrier gas at a flow rate of 500 sccm to 1000 sccm and preferably 900 sccm, and a nitrogen carrier gas at a flow rate of 100 sccm to 1000 sccm and preferably 100 sccm under a pressure of 133 Pa to 10.6 kPa and preferably 2.7 kPa at a substrate temperature of 300° C. to 470° C. and preferably 410° C.

In FIG. 1D, the tungsten burying layer 18 is depicted to include the initial tungsten film 17.

In general, reduction of WF₆ with hydrogen selectively occurs at the solid/gas interface and thus the tungsten burying layer 18 is sequentially deposited on the initial tungsten film 17 and fills the contact hole 14A with good step coverage. Although the tungsten raw material is reduced with hydrogen in the step illustrated in FIG. 1D, the problem of reduction of the upper electrode 12C and the ferroelectric film 12B by hydrogen penetration does not occur since the side wall surface and the bottom surface of the contact hole 14A are covered with the initial tungsten film 17 with good step coverage as illustrated in FIG. 1C.

The structure of FIG. 1D is chemically mechanically polished (CMP) to remove the tungsten burying layer 18 and the barrier metal film 15 on the interlayer insulating film 14 to obtain a tungsten plug 18A filling the contact hole 14A, as illustrated in FIG. 1E. Electron probe micro analysis (EPMA), for example, has confirmed that in the state illustrated in FIG. 1E, the silicon-rich layer 16 still remains at the interface between the barrier metal film 15 and the tungsten plug 18A.

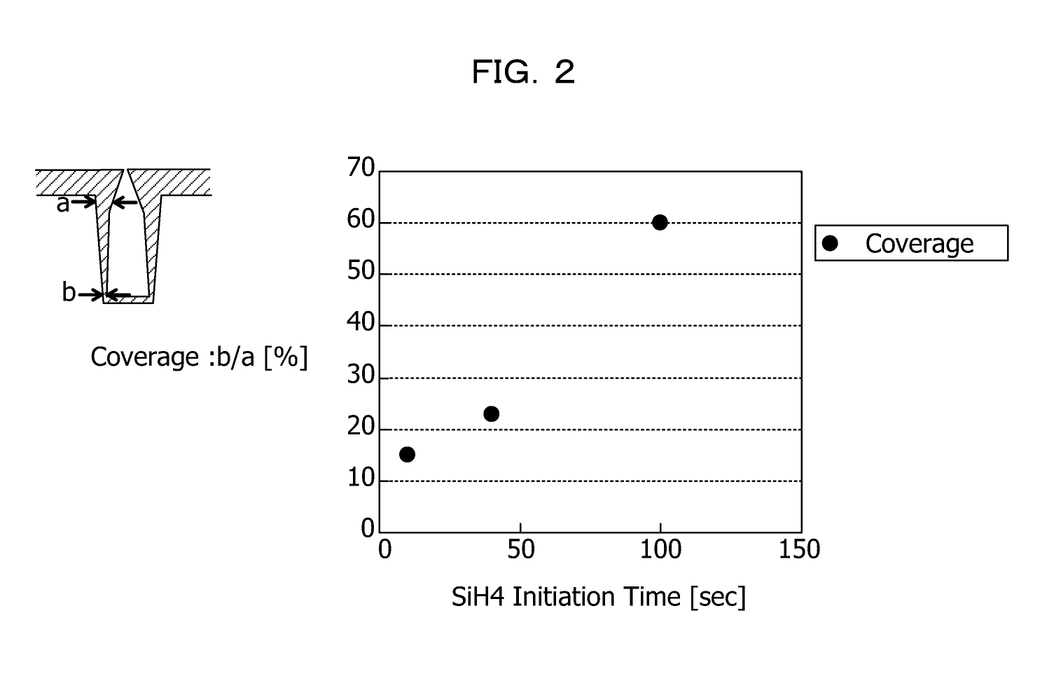

FIG. 2 is a graph representing the relationship between the duration of the initialization step illustrated in FIG. 1A and the step coverage b/a of the initial tungsten film 17 formed in the contact hole 14A. The step coverage b/a is the film thickness b of the initial tungsten film 17 covering the side wall surface of the contact hole 14A divided by the thickness a of the initial tungsten film 17 deposited on the flat surface as defined in FIG. 2.

The graph in FIG. 2 indicates that the step coverage b/a asymptotically increases from a value near zero toward 1 as the duration of the initialization step increases.

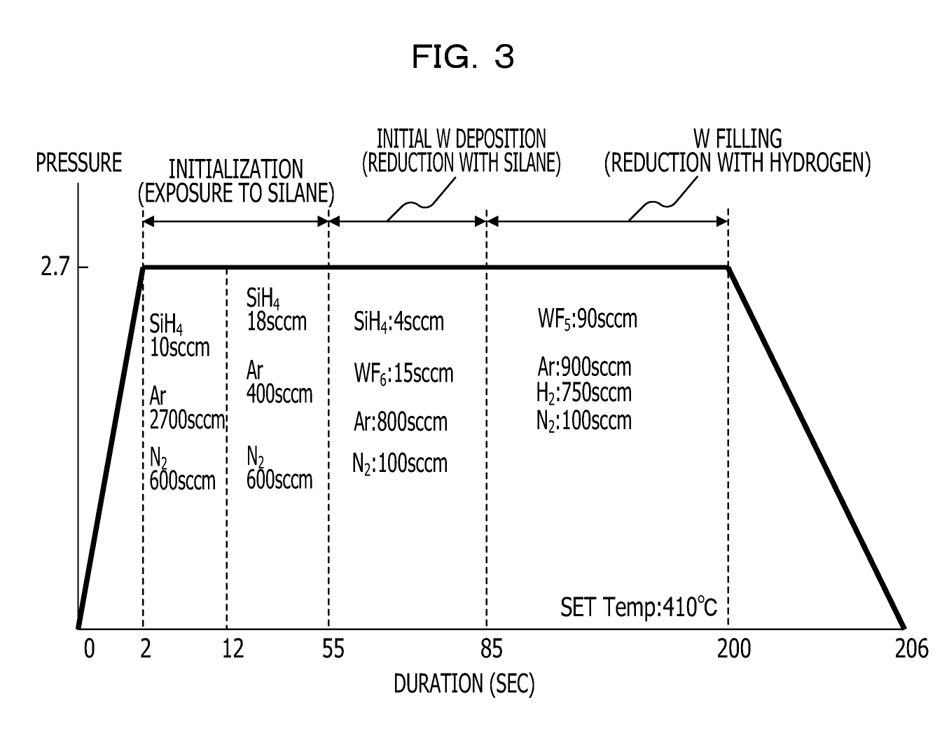

FIG. 3 is a graph indicating an example of a recipe used in the steps illustrated in FIGS. 1A to 1D.

Referring to FIG. 3, after the substrate to be processed having the structure illustrated in FIG. 1A is charged into a processing apparatus, feeding of an argon gas and a nitrogen gas is started. The pressure inside the processing apparatus increases with time and reaches a particular pressure, e.g., 2.7 kPa (20 Torr), after 2 seconds. The pressure inside the processing apparatus is maintained at this particular value hereafter.

When the pressure inside the processing apparatus reaches the particular value, feeding of a silane gas is started at a flow rate of 10 scan and thus the initialization step illustrated in FIG. 1A is started. Twelve seconds after the start of pressure elevation, the flow rate of the argon carrier gas is reduced to 400 sccm and the flow rate of the silane gas is increased to 18 sccm to perform the initialization step. In the example indicated in the graph, the net duration of the initialization step is set to 53 seconds; however, as mentioned above, the duration of the initialization step of the present invention is not limited to 53 seconds and the initialization step may be continued for 100 seconds or longer.

After the initialization step, the flow rate of the argon carrier gas is increased to 800 sccm, the flow rate of the nitrogen carrier gas is decreased to 100 sccm, the flow rate of the silane gas is decreased to 4 sccm, and the feeding of the WF₆ gas serving as the tungsten raw material is started at a flow rate of 15 sccm. This marks the start of the step of forming the initial tungsten film 17 illustrated in FIG. 1C. In the recipe indicated in the graph, the step illustrated in FIG. 1C is continued for 30 seconds.

After the step of forming the initial tungsten film, a tungsten filling step illustrated in FIG. 1D is started by increasing the flow rate of WF₆ to 90 sccm and starting the feeding of hydrogen gas at a flow rate of 750 sccm. In the example indicated in the graph, the tungsten filling step is continued for 115 seconds.

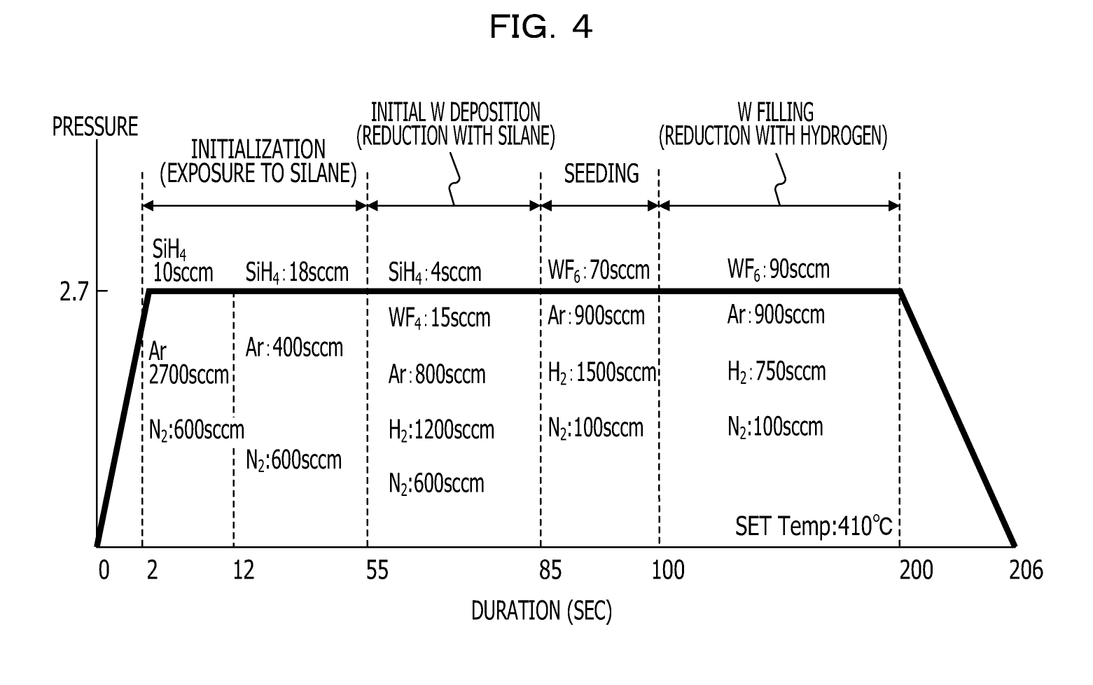

In general, in forming a tungsten film, a seeding step of delivering the tungsten source gas at a high flow rate is frequently conducted in advance to form seeds. In this embodiment also, a recipe illustrated in FIG. 4 that includes a seeding step between the initial tungsten film forming step illustrated in FIG. 1C and the tungsten film filling step illustrated in FIG. 1D may be used instead of the recipe illustrated in FIG. 3.

The method for forming the tungsten contact plug according to this embodiment is applicable to those electronic apparatuses in general which include metal oxide films susceptible to losing their characteristics by reduction with hydrogen. Examples of such electronic apparatuses include ferroelectric memories (FeRAMs) and magnetic random access memories (MRAMs) described below.

In the step illustrated in FIG. 1A or 1C in this embodiment, 2 moles of hydrogen gas is released by decomposition of 1 mole of silane gas. Accordingly, the atmosphere used in the step illustrated in FIG. 1A or 1C is preferably free of hydrogen gas but may contain a small quantity of hydrogen gas, i.e., typically a hydrogen gas at a flow rate of about twice the flow rate of the silane gas.

In this embodiment, the initial tungsten film 17 is formed using silane as a reductant in the step illustrated in FIG. 1C. As a result, silicon atoms and hydrogen atoms are homogeneously contained in the tungsten plug formed and thus the variation of stress inside the tungsten plug that occurs due to removal of the tungsten burying layer 18 and the barrier metal film 15 by CMP illustrated in FIG. 1E is reduced. Accordingly, the stress applied on the side wall surface of the contact hole and corner portions onto which tungsten does not adhere closely is reduced, separation and cracking of the tungsten plug are suppressed, and the failure caused by the contact plug is reduced. Since silicon atoms derived from silane gas are homogeneously distributed in the tungsten plug, hydrogen penetrating through, for example, a seam inside the tungsten plug 18A is captured by silicon atoms remaining in parts of the initial tungsten film 17 or the silicon-rich layer 16. Thus, reduction of the ferroelectric films and the upper electrode of the ferroelectric capacitor composed of an electrically conductive oxide such as iridium oxide is effectively suppressed.

What is concerned about forming the initial tungsten film 17 by reduction with silane in the step illustrated in FIG. 1C is the step coverage of the initial tungsten film 17 formed thereby. In this embodiment, since the silicon-rich layer 16 is formed on the surface of the barrier metal film 15, the initial tungsten film 17 is formed with good step coverage using the silicon atoms as the seeds.

When the contact hole has a high aspect ratio, e.g., an aspect ratio of 10 or more, the step coverage of the initial tungsten film 17 may deteriorate. However, in such a case, formation of the initial tungsten film 17 may be divided over plural steps. For example, a process of depositing a thin layer, milling the thin layer by CMP or etching back, and reducing the thin layer with silane again may be repeated several times to form the initial tungsten film 17 with high step coverage.

In this embodiment, the upper electrode 12C may be formed of a ruthenium oxide film, a strontium ruthenium oxide film, a strontium titanate film, or the like instead of the iridium oxide film.

The first embodiment described above may be summarized as follows. When the initialization step of exposing the side wall surface and bottom surface of the contact hole to a silane gas is conducted immediately before a tungsten film is formed to fill the contact hole exposing the upper electrode composed of an electrically conductive oxide, the side wall surface and bottom surface of the contact hole are at least covered with silicon atoms forming a monoatomic layer. As a result, the step coverage of the tungsten film formed on the silicon monoatomic layer is improved. When the initialization step is performed in an atmosphere containing no hydrogen or very little hydrogen at a flow rate twice the flow rate of the silane gas or less, reduction of the electrically conductive oxide constituting the upper electrode or the ferroelectric film formed under the upper electrode may be suppressed. In particular, when the initial tungsten deposition step of reducing the tungsten source gas with a silane gas is provided after the initialization step, the side wall surface and bottom surface of the contact hole are covered with a tungsten film without using hydrogen or while suppressing the hydrogen flow rate to a minimum level. Thus, in the subsequent tungsten filling step involving reduction with hydrogen, the problem that the hydrogen in the atmosphere reaches the upper electrode and reduces the electrically conductive oxide does not occur. In general, a tungsten film formed by reducing the raw material of tungsten with a silane gas tends to be poor in terms of step coverage. However, in this embodiment, since the side wall surface and bottom surface of the contact hole are covered with silicon atoms by conducting the initialization step beforehand, the tungsten film is formed with high step coverage in the initial tungsten deposition step.

### Second Embodiment

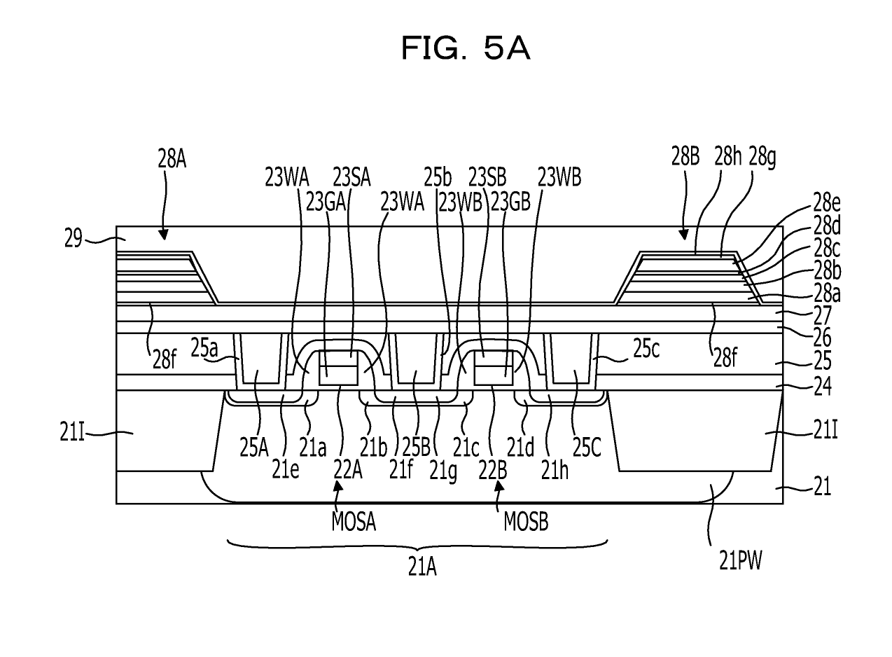

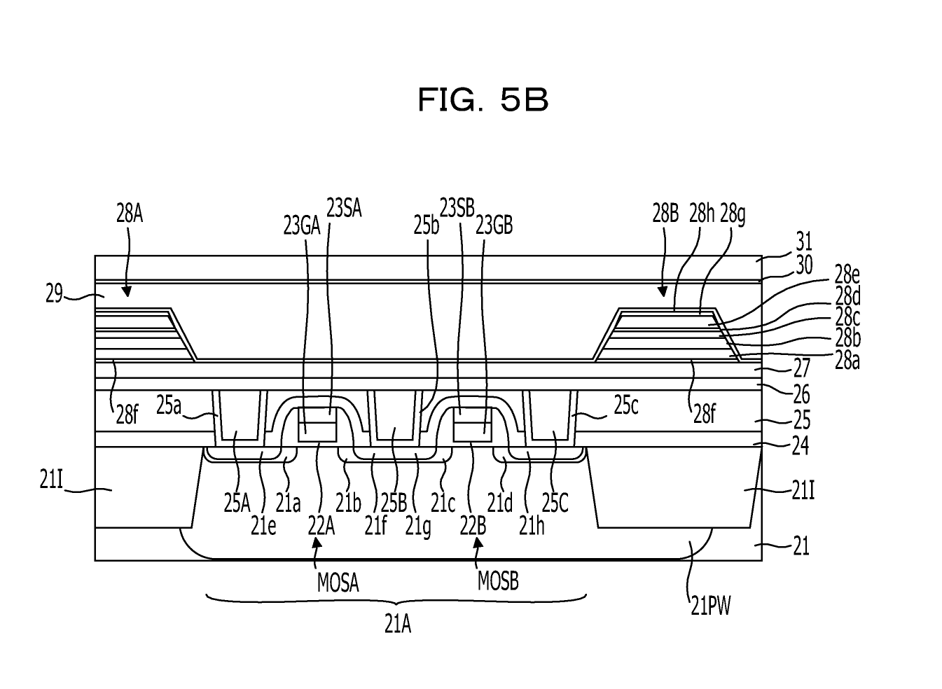

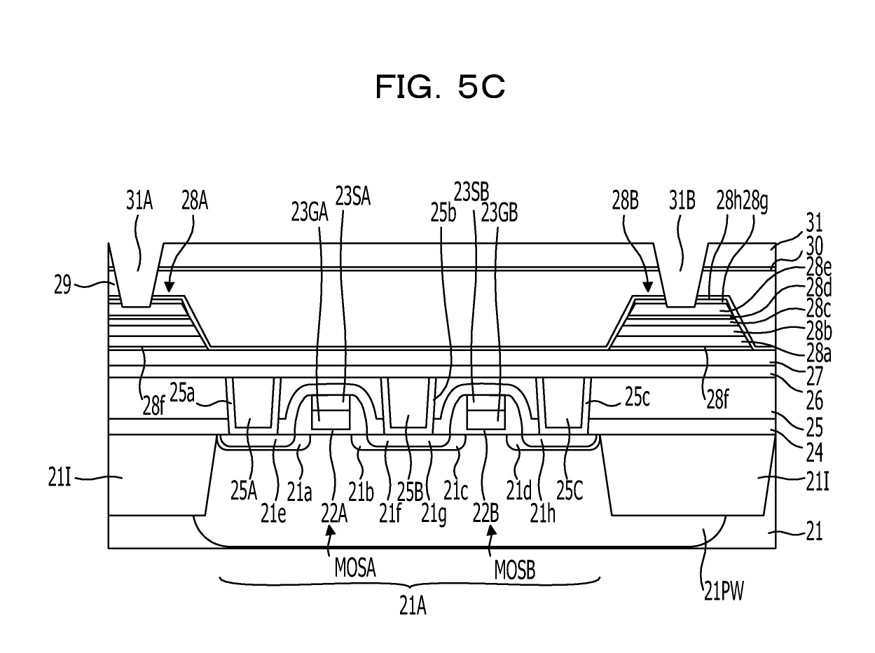

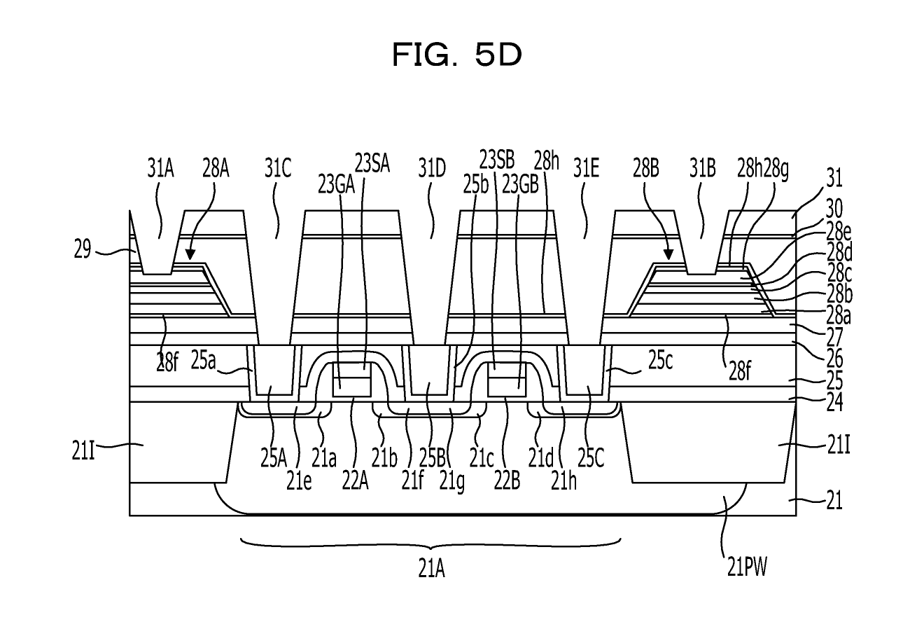

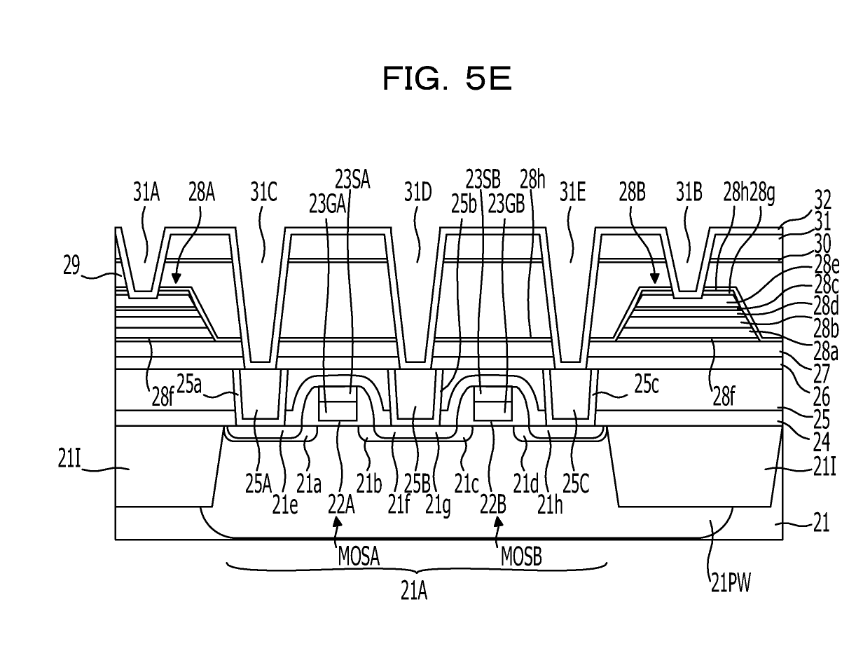

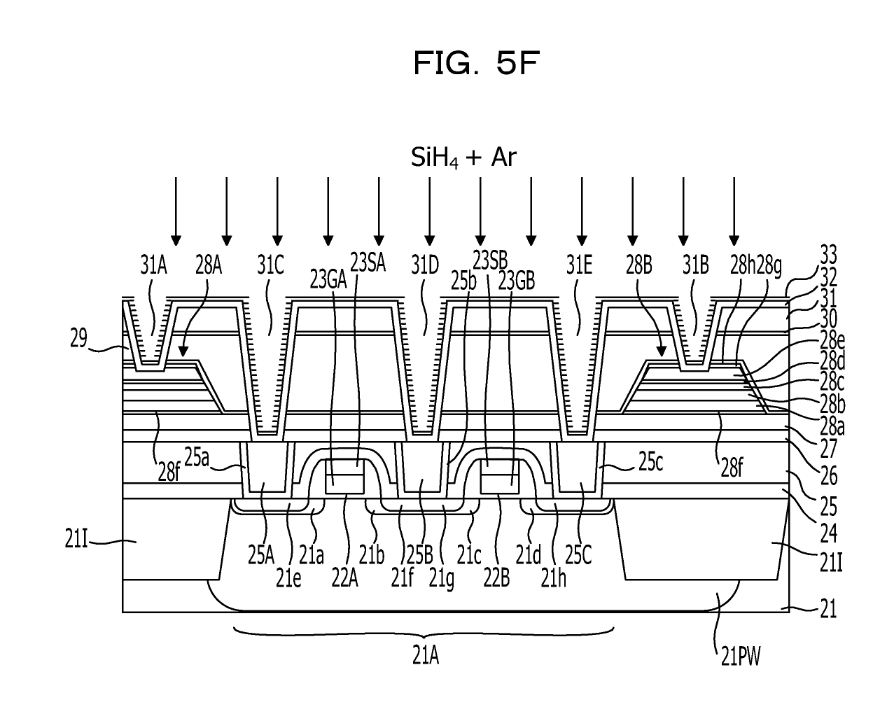

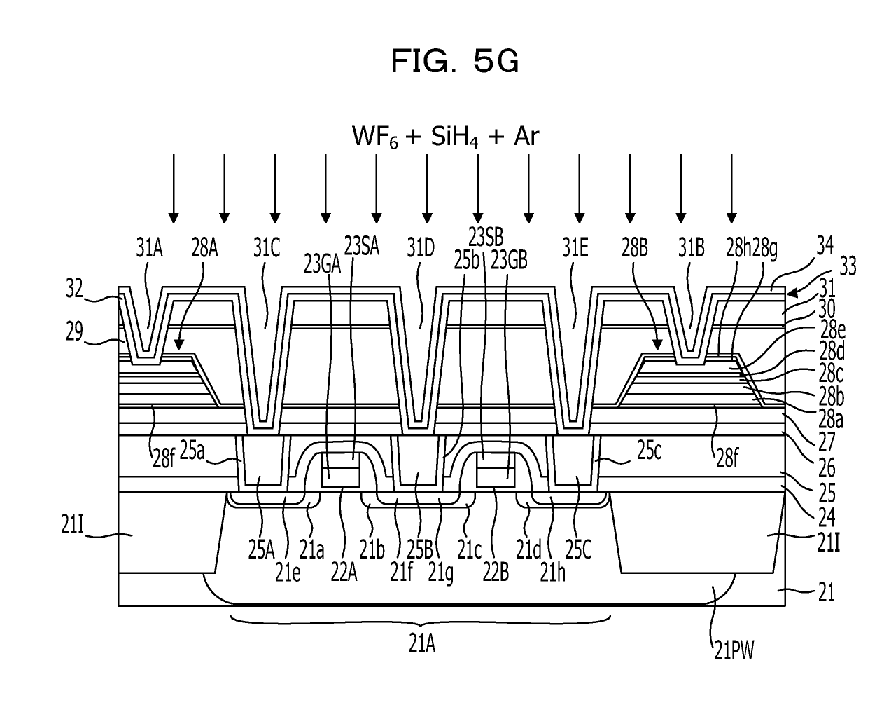

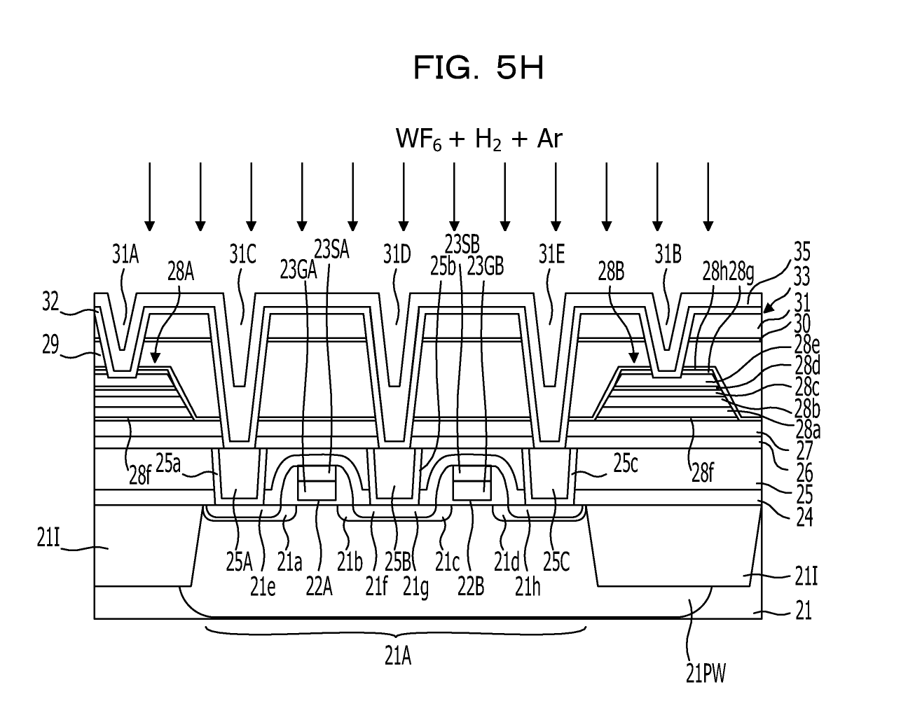

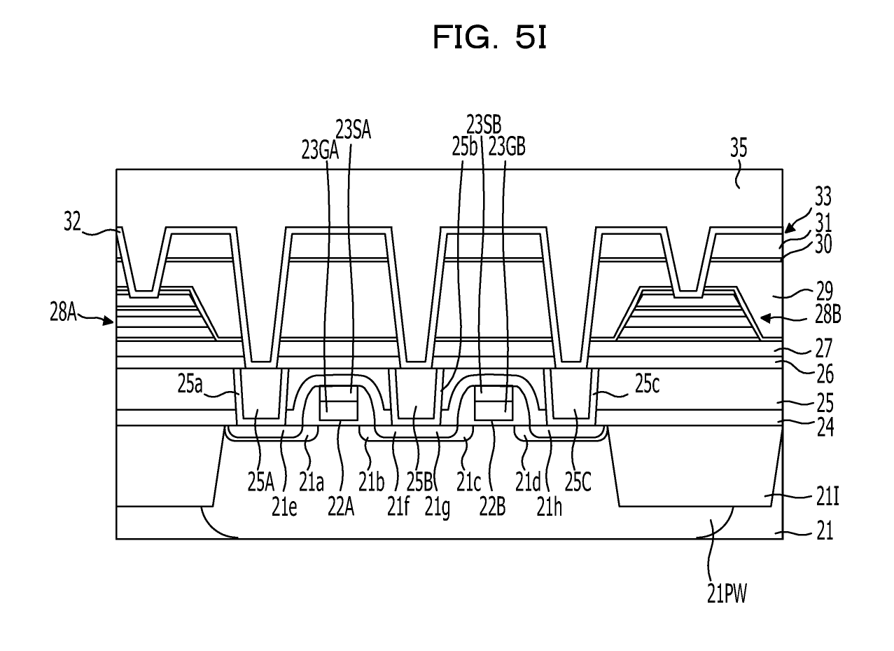

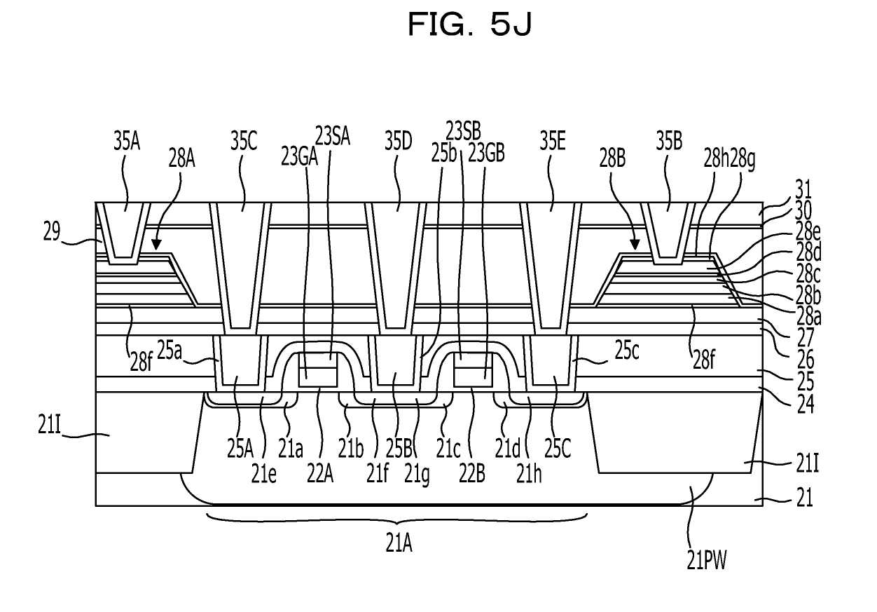

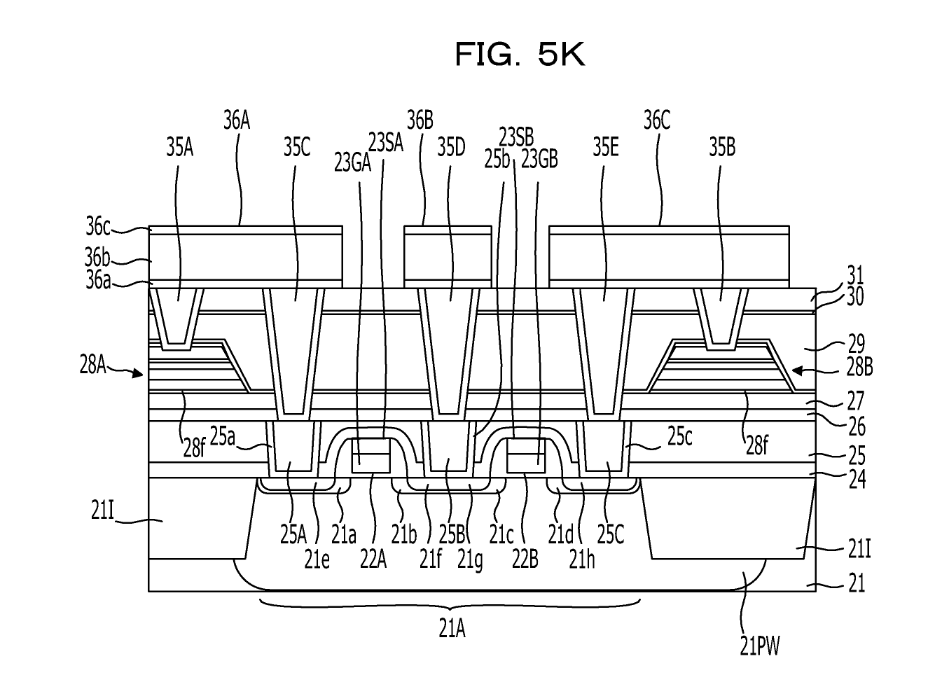

A method for making a ferroelectric memory (FeRAM) according to a second embodiment of the present invention will now be described with reference to FIGS. 5A to 5T.

Referring first to FIG. 5A, a device isolation structure 21I of a shallow trench isolation (STI) type for defining an active region 21A of a transistor is formed on a n- or p-type silicon (semiconductor) substrate surface. However, in this embodiment, the device isolation structure is not limited to the STI structure and may be formed by a local oxidation of silicon (LOCOS) technique.

A p-well 21PW containing a p-type impurity is formed in the active region 21A of a silicon substrate 21. A thermal oxide film that serves as a gate insulating film is formed on the surface of the p-well 21PW.

A gate electrode 23GA and a gate electrode 23GB are formed by patterning an amorphous or polycrystalline silicon film on the silicon substrate 21. Gate insulating films 22A and 22B are respectively formed under the gate electrode 23GA and the gate electrode 23GA by patterning the thermal oxide film. The gate electrodes 23GA and 23GB are disposed on the p-well 21PW in parallel with each other with a space therebetween to respectively form part of word lines. Channel regions respectively corresponding to the gate electrode 23GA and the gate electrode 23GB are formed directly under the gate electrode 23GA and the gate electrode 23GB, the channel regions being formed in the p-well 21PW in the active region 21A.

In the silicon substrate 21, an n-type source extension region 21a and an n-type drain extension region 21b are respectively formed in regions adjacent to the gate electrode 23GA by injecting ions of an n-type impurity using the gate electrodes 23GA and 23GB as masks. At the same time, in the silicon substrate 21, an n-type source extension region 21c and an n-type drain extension region 21d are respectively formed in regions adjacent to the gate electrode 23GB. The drain extension regions 21b and 21c are actually formed as one impurity-diffused region.

An insulating side wall 23WA is formed on side wall surface of the gate electrode 23GA by depositing an insulating film on the entire upper surface of the silicon substrate 21 and then etching back the insulating film. A similar insulating side wall 23WB is formed on the side wall surface of the gate electrode 23GB. The insulating side walls may be formed by, for example, depositing a silicon oxide film by a CVD method.

An n-type source region 21e and an n-type drain region 21f are formed in the silicon substrate 21 in regions outside the insulating side wall 23WA of the gate electrode 23GA by injecting ions of an n-type impurity into the silicon substrate 21 again while using the insulating side wall 23WA, the gate electrode 23GA, and the insulating side wall 23WB as masks. In the silicon substrate 21, an n-type source region 21g and an n-type drain region 21h are formed in regions outside the insulating side wall 23WB of the gate electrode 23GB in a similar manner. The n-type drain region 21f and the n-type source region 21g are formed as one impurity-diffused region.

As a result, the active region 21A of the silicon substrate 21 includes a first metal oxide semiconductor (MOS) transistor MOSA having the gate electrode 23GA, and a second metal oxide semiconductor (MOS) transistor MOSB having the gate electrode 23GB.

The exposed surfaces of the n-type source region 21e, the n-type drain region 21f, the n-type source region 21g, and the n-type drain region 21h are provided with a refractory metal silicide layer (not illustrated in the drawing) formed by sputter-depositing a refractory metal layer such as a cobalt layer on the entire surface of the silicon substrate 21 and then heating the refractory metal layer to cause a reaction between the refractory metal layer and silicon. Similar refractory metal silicide layers are also formed on the surface portions of the gate electrodes 23GA and 23GB and respectively serve as a silicide layer 23SA and a silicide layer 23SB that reduce the wiring resistance of the gate electrodes 23GA and 23GB.

According to the structure illustrated in FIG. 5A, a SiON film that serves as an oxygen barrier film 24 and has a thickness of about 200 nm is formed by a plasma-enhanced CVD method on the silicon substrate 21, the gate electrodes 23GA and 23GB, and insulating side walls 23WA and 23WB. A first interlayer insulating film 25 formed of a silicon oxide film is formed on the oxygen barrier film 24 by a plasma-enhanced CVD technique using a TEOS gas.

The upper surface of the first interlayer insulating film 25 is planarized by chemical mechanical polishing (CMP). As a result of the CMP, the first interlayer insulating film 25 has a thickness of about 700 nm on the flat portion of the silicon substrate 21.

Contact holes that penetrate the oxygen barrier film 24, expose the n-type source region 21e and the n-type drain region 21f of the transistor MOSA and the n-type source region 21g of the transistor MOSB, and have a diameter of 0.25 μm, for example, are formed in the first interlayer insulating film 25. Similarly, a contact hole that penetrates the oxygen barrier film 24, exposes the n-type drain region 21h of the transistor MOSB, and has a diameter of 0.25 μm, for example, is formed in the first interlayer insulating film 25. Tungsten plugs 25A, 25B, and 25C that make electrical contact with the impurity-diffused regions 21e to 21f are formed in these contact holes by a CVD technique. Adhesive films (glue films) 25a to 25c each having a multilayer structure constituted by a 30 nm-thick Ti film and a 20 nm-thick TiN film are interposed between the tungsten plugs 25A to 25C and the impurity-diffused regions 21e to 21f.

A first anti-oxidation film 26 composed of SiON having a thickness of, for example, 100 nm is formed by a CVD method on the first interlayer insulating film 25 in which the tungsten plugs 25A to 25C are formed. A second interlayer insulating film 27 formed of a silicon oxide film by a plasma-enhanced CVD method using TEOS as the raw material is formed on the first anti-oxidation film 26. The thickness of the second interlayer insulating film 27 is, for example, 130 nm.

A first ferroelectric capacitor 28A and a second ferroelectric capacitor 28B that respectively correspond to the transistor MOSA and the transistor MOSB are formed on the second interlayer insulating film 27. The first ferroelectric capacitor 28A and the second ferroelectric capacitor 28B are each prepared by sequentially stacking a lower electrode 28a which is composed of platinum (Pt) and has the (111) orientation, a first capacitor insulating film 28b which is a PZT film prepared by a sputtering method, a sol-gel method, a CVD method, or the like and has the (111) orientation, a second capacitor insulating film 28c which is also a PZT film and has the (111) orientation, a first upper electrode film 28d which is formed of an electrically conductive metal oxide film such as IrOx and has a non-stoichiometric composition (x<2), and a second upper electrode film 28e having a stoichiometric composition, such as IrO₂, or a composition close to stoichiometric.

The ferroelectric capacitors 28A and 28B are formed on a thin aluminum oxide (Al₂O₃) film 28f having a thickness of about 20 nm on the second interlayer insulating film 27. In this manner, the crystal orientation of the platinum film constituting the lower electrode 28a is effectively regulated to the desired (111) orientation.

To be more specific, the platinum film constituting the lower electrode 28a is formed to a thickness of about 100 nm, for example, in an argon atmosphere at a substrate temperature of 350° C. and a 0.2 kW sputtering power. However, the platinum film formed as such is further subjected to a rapid heat treatment at 650° C. to 750° C. for 60 seconds in an inert gas (e.g., Ar) atmosphere and has good crystallinity and (111) orientation. Alternatively, the lower electrode 28a may be composed of iridium (Ir) or an electrically conductive oxide such as platinum oxide (PtO), iridium oxide, or strontium ruthenium oxide (SrRuO₃) instead of platinum.

The PZT film constituting the first capacitor insulating film 28b is, for example, formed to a thickness of 50 nm to 100 nm under a pressure of 0.5 to 1.0 Pa at a substrate temperature of room temperature to 200° C. and a sputter power of 0.1 kW to 1 kW in an argon-oxygen mixed atmosphere with an argon gas flow rate of 1500 sccm and an oxygen gas flow rate of 30 sccm. The PZT film is then continuously subjected to a heat treatment at a temperature of 500° C. to 800° C. in an oxygen atmosphere to be crystallized and have oxygen deficiencies compensated. As a result, the desired (111) orientation and good electrical characteristics are achieved.

The PZT film constituting the second capacitor insulating film 28c is, for example, formed to a thickness of 25 nm under a pressure of 0.5 Pa at a substrate temperature of 200° C. or less and a sputter power of 0.5 kW in an argon-oxygen mixed atmosphere with an argon gas flow rate of 1500 sccm and an oxygen gas flow rate of 30 sccm but is not immediately subjected to a heat treatment in an oxidizing atmosphere. After formation of the PZT film constituting the second capacitor insulating film 28c, the first upper electrode film 28d composed of iridium oxide having a non-stoichiometric composition is formed on the PZT film (second capacitor insulating film 28c) to a thickness of 50 nm under a pressure of 0.8 Pa at a substrate temperature of 300° C. and a sputter power of 1 kW to 2 kW in an argon-oxygen mixed atmosphere with an argon flow rate of 140 sccm and an oxygen gas flow rate of 60 sccm. Then the first upper electrode film 28d and the second capacitor insulating film 28c are simultaneously heated at 725° C. for 60 seconds in an oxygen atmosphere, e.g., a mixed atmosphere of argon and oxygen. As a result, the second capacitor insulating film 28c is crystallized while achieving the desired (111) orientation and, at the same time, the oxygen deficiencies are compensated. When an iridium oxide film having a non-stoichiometric composition is directly formed on the sputter-deposited PZT film and then a heat treatment is performed in an oxygen atmosphere, a flat stable interface is obtained between the PZT film constituting the second capacitor insulating film 28c having the (111) orientation and the iridium oxide film constituting the first upper electrode film 28d. When this heat treatment is conducted, damage caused by sputter-depositing the iridium oxide film on the second capacitor insulating film 28c (PZT film) is recovered.

The iridium oxide film having the stoichiometric composition and constituting the second upper electrode film 28e is formed to a thickness of 50 nm to 150 nm by performing sputter deposition in an argon atmosphere under a pressure of 0.8 Pa at a 1.0 kW sputter power for 45 seconds. During the sputter-deposition, in order to suppress abnormal growth of iridium oxide, the substrate temperature is controlled to 100° C. or less. The iridium oxide thus formed has a composition close to a stoichiometric composition, i.e., IrO₂.

A layered structure constituted by the layers 28a to 28e thus formed is patterned into the first ferroelectric capacitor 28A and the second ferroelectric capacitor 28B by dry-etching the layered structure by using a hard mask pattern (not illustrated) formed on the iridium oxide film constituting the second upper electrode film 28e. This hard mask pattern is composed of, for example, titanium nitride (TiN) and formed to correspond the transistors MOSA and MOSB. Then the hard mask pattern is removed by wet-etching from the first ferroelectric capacitor 28A and the second ferroelectric capacitor 28B obtained thereby and an oxygen deficiency-compensating process involving a heat treatment is performed in an oxygen atmosphere. The side wall surfaces and the top surfaces of the first and second ferroelectric capacitors 28A and 28B are covered with a first aluminum oxide film that has a thickness of about 50 nm and serves as a first hydrogen barrier film 28g and a second aluminum oxide film that has a thickness of about 20 nm and serves as a second hydrogen barrier film 28h. According to the structure of this embodiment, since the iridium oxide film constituting the second upper electrode film 28e has a stoichiometric composition or a composition close to the stoichiometric composition, the contact between the second upper electrode film 28e and the hydrogen gas does not cause the hydrogen catalytic effect. Thus, the problem of reduction of the first capacitor insulating film 28b and the second capacitor insulating film 28c with hydrogen radicals is suppressed and the hydrogen resistance of the capacitors is improved.

In this embodiment, strontium ruthenium oxide (SrRuO₃) films having a thickness of 50 nm to 150 nm may be used as the first upper electrode film 28d and the second upper electrode film 28e instead of the iridium oxide films.

The first ferroelectric capacitor 28A and the second ferroelectric capacitor 28B formed as such are heated, for example, at 550° C. to 700° C. for 60 minutes in an oxygen-containing atmosphere to recover the damage on the first capacitor insulating film 28b and the second capacitor insulating film 28c composed of PZT.

According to the structure illustrated in FIG. 5A, an interlayer insulating film 29 composed of silicon oxide and having a thickness of, for example, 1400 nm is formed by a plasma CVD method typically using TEOS as the raw material on the entire surface of the silicon substrate 21 so as to cover the first ferroelectric capacitor 28A and the second ferroelectric capacitor 28B. When a silicon oxide film is formed as the interlayer insulating film 29, a mixed gas of a TEOS gas, an oxygen gas, and a helium gas may be used as the source gas. An insulating inorganic film, for example, may be formed as the interlayer insulating film 29. The surface of the interlayer insulating film 29 is planarized by, for example, CMP or the like after its formation. The interlayer insulating film 29 formed as such is heated in a plasma atmosphere generated by using an N₂O gas, a nitrogen gas, or the like to remove water in the interlayer insulating film 29. This changes the quality of the interlayer insulating film 29 and suppresses penetration of water into the interlayer insulating film 29.

Next, as illustrated in FIG. 5B, an aluminum oxide film having a thickness of, for example, 20 nm to 100 nm is formed as a barrier film (third protective insulating film) 30 on the entire surface of the interlayer insulating film 29 by sputtering or CVD, for example. Since the barrier film 30 is formed on the planarized interlayer insulating film 29, the barrier film 30 is flat. Because of the presence of the flat barrier film 30, deterioration of the first upper electrode film 28d, the second upper electrode film 28e, the first capacitor insulating film 28b, and the second capacitor insulating film 28c that will occur due to the subsequent processes will be suppressed to a minimum level.

Another interlayer insulating film 31 is formed on the entire surface of the barrier film 30 by plasma-enhanced CVD using, for example, TEOS as the raw material as illustrated in FIG. 5B. For example, a silicon oxide film having a thickness of 300 nm to 500 nm may be used as the interlayer insulating film 31. The interlayer insulating films 29 and 31 are not limited to CVD films using the TEOS raw material and may be any other organic or inorganic low-dielectric-constant insulating film (a.k.a., low-k film), for example. The method for making the interlayer insulating films 29 and 31 is not limited to the plasma-enhanced CVD. For example, a coating technique may be used to form these films.

Referring to FIG. 5C, contact holes 31A and 31B are formed in the interlayer insulating film 31. The contact holes 31A and 31B penetrate the barrier film 30, the interlayer insulating film 29, and the second hydrogen barrier film 28h and the first hydrogen barrier film 28g covering the first and second ferroelectric capacitors 28A and 28B underneath the interlayer insulating film 31 and are respectively formed at positions corresponding to the first ferroelectric capacitor 28A and the second ferroelectric capacitor 28B so as to expose the upper electrode films 28e of these capacitors.

In this state, for example, a heat treatment at 450° C. is performed for 60 minutes in an oxygen atmosphere to release the water in the interlayer insulating films 29 and 31 through the contact holes 31A and 31B. Such removal of water through contact holes is called “stack effect”. Although not illustrated in the drawing, in the step illustrated in FIG. 5C, contact holes extending to the lower electrodes 28a are also formed at the same time as forming the contact holes 31A and 31B and the same stack effect occurs also in the contact holes for the lower electrodes. When the heat treatment is conducted in an oxygen atmosphere, oxygen elimination from the iridium oxide films constituting the upper electrode films 28e exposed in the contact holes 31A and 31B is avoided.

Since the heat treatment in the step illustrated in FIG. 5C is conducted at a relatively low temperature of about 450° C., the effect of oxygen entering through the contact holes 31A and 31B on the recovery of the electric characteristics of the first capacitor insulating film 28b and the second capacitor insulating film 28c is small. However, hydrogen trapped at the interface between the first upper electrode film 28d (iridium oxide film) included in the upper electrode and the second capacitor insulating film 28c leaves the interface due to thermal energy. As a result, the switching characteristics of the first ferroelectric capacitor 28A and the second ferroelectric capacitor 28B are improved despite the low temperature used in the heat treatment.

When the heat treatment temperature after formation of the contact holes 31A and 31B is high, the lower electrically conductive oxide film of the upper electrode, i.e., the iridium oxide film having a non-stoichiometric composition IrOx or the strontium oxide film having a non-stoichiometric composition, tends to undergo abnormal growth. Thus, the heat treatment temperature in the step illustrated in FIG. 5C is preferably as low as possible. For this reason, the heat treatment illustrated in FIG. 5C is preferably performed in the temperature range of 450° C. to 500° C.

In the step illustrated in FIG. 5C, when the heat treatment is conducted in a nitrogen atmosphere instead of an oxygen atmosphere, oxygen in the electrically conductive oxide films, such as iridium oxide films, constituting the first upper electrode film 28d and the second upper electrode film 28e is removed and thus the volume of the upper electrode is changed. Thus, the heat treatment is preferably conducted in an oxygen atmosphere.

Next, as illustrated in FIG. 5D, contact holes 31C to 31E corresponding to the tungsten plugs 25A, 25B, and 25C are formed in the interlayer insulating film 31 by penetrating the barrier film 30, the interlayer insulating film 29, the second hydrogen barrier film 28h, the second interlayer insulating film 27, and the first anti-oxidation film 26 underneath the interlayer insulating film 31. The bottoms of the contact holes 31C to 31E respectively expose the tungsten plugs 25A, 25B, and 25C.

Referring now to FIG. 5E, a TiN film is sputter-deposited on the structure illustrated in FIG. 5D so that the TiN film serves as a barrier metal film 32. The TiN film constituting the barrier metal film 32 covers the side wall surfaces and bottom surfaces of the contact holes 31A to 31E. Since a Ti film widely used as a base adhesive film for forming a TiN barrier metal film forms titanium oxide by bonding with oxygen in the upper electrode film (iridium oxide film) 28e of the upper electrode and increases the contact resistance, the barrier metal film 32 of this embodiment is preferably formed as a single-layered TiN film.

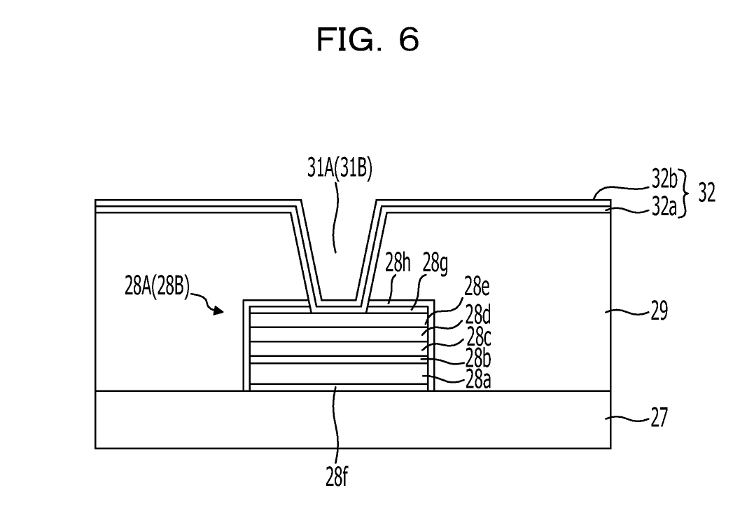

Instead of the TiN film, a TaN film may be formed as the barrier metal film 32. However, when a tungsten film is formed on TaN by CVD, reliability problems such as corrosion may arise. Thus, in forming a TaN film as the barrier metal film 32, a TiN film is preferably formed on the TaN film so that the barrier metal film 32 has a two-layer structure including a first barrier metal film 32a and a second barrier metal film 32b illustrated in FIG. 6. According to this barrier metal film 32 having a two-layer structure, deterioration of reliability caused by use of a TaN film is avoided and the growth lines formed in the lower TaN film by sputter deposition are suppressed from becoming continuous with the growth lines formed in the upper TiN film by sputter deposition. Thus, penetration of hydrogen along the growth lines is effectively suppressed. The barrier metal film having the two-layer structure illustrated in FIG. 6 may be formed by stacking a TiN film and another TiN film. In such a case also, penetration of hydrogen through the growth lines is effectively suppressed.

Next, in the step illustrated in FIG. 5F corresponding to the initialization step illustrated in FIG. 1A, the structure illustrated in FIG. 5 is exposed to a silane gas atmosphere to form a silicon-rich layer 33, which corresponds to the silicon-rich layer 16 described with reference to FIG. 1B, on the surface of the barrier metal film 32.

In the step illustrated in FIG. 5G that corresponds to the step illustrated in FIG. 1C, a WF₆ gas is supplied as a tungsten source gas together with a silane gas serving as a reductant gas to form an initial tungsten layer 34 having a thickness of, e.g., 10 nm to 30 nm on the barrier metal film 32.

In the steps illustrated in FIGS. 5F and 5G, no hydrogen gas is preferably added to the atmosphere. Alternatively, a hydrogen gas may be used as long as the hydrogen gas flow rate is about twice the flow rate of the silane gas.

In the step illustrated in FIG. 5H that corresponds to the step illustrated in FIG. 1D, a WF₆ gas is supplied as a tungsten source gas and a hydrogen gas is supplied as a reductant gas along with an argon carrier gas over the structure illustrated in FIG. 5G to form a tungsten burying layer 35 on the initial tungsten layer 34 and fill the contact holes 31A to 31E. FIG. 5I illustrates a state in which the contact holes 31A to 31E are completely filled with the tungsten burying layer 35. The tungsten burying layer 35 is depicted to include the initial tungsten layer 34.

As described earlier, a hydrogen gas is used as the reductant gas in the step of FIG. 5H. However, the contact holes 31A and 31B exposing the upper electrodes of the first ferroelectric capacitor 28A and the second ferroelectric capacitor 28B are already covered with the initial tungsten layer 34 in the step illustrated in FIG. 5G. Thus, penetration of hydrogen into the interiors of the first ferroelectric capacitor 28A and the second ferroelectric capacitor 28B is effectively suppressed even when the tungsten burying layer 35 is deposited using hydrogen as the reductant gas.

Next, referring to FIG. 53, a portion of the tungsten burying layer 35 above the interlayer insulating film 31 and the barrier metal film 32 on the interlayer insulating film 31 are removed by chemical mechanical polishing. As a result, tungsten plugs 35A to 35E are formed in the contact holes 31A to 31E.

Referring to FIG. 5K, wiring patterns 36A, 36B, and 36C that correspond to the tungsten plugs 35A to 35E are formed on the interlayer insulating film 31. In the step illustrated in FIG. 5K, for example, an adhesive layer 36a having a Ti/TiN layered structure constituted by a Ti film 60 nm in thickness and a TiN film 30 nm in thickness, an AlCu alloy film 36b 360 nm in thickness, and an adhesive layer 36c having a Ti/TiN layered structure constituted by a Ti film 5 nm in thickness and a TiN film 70 nm in thickness are sequentially formed by sputtering to form a wiring layer. This wiring layer is photolithographically patterned to form the wiring patterns 36A, 36B, and 36C.

Then additional interlayer insulating films and contact plugs are formed as needed to form a desired multilevel wiring structure.

In this embodiment also, the steps illustrated in FIGS. 5F to 5H may be performed according to the recipe illustrated in FIG. 3 or 4.

In this embodiment, ruthenium oxide films, strontium ruthenium oxide films, strontium titanate films, etc., may be used as the first upper electrode film 28d and the second upper electrode film 28e instead of the iridium oxide films.

### Third Embodiment

The previous embodiments are directed to FeRAMs; however, the technology disclosed in this application may be widely applied to other types of semiconductor and electronic apparatuses.

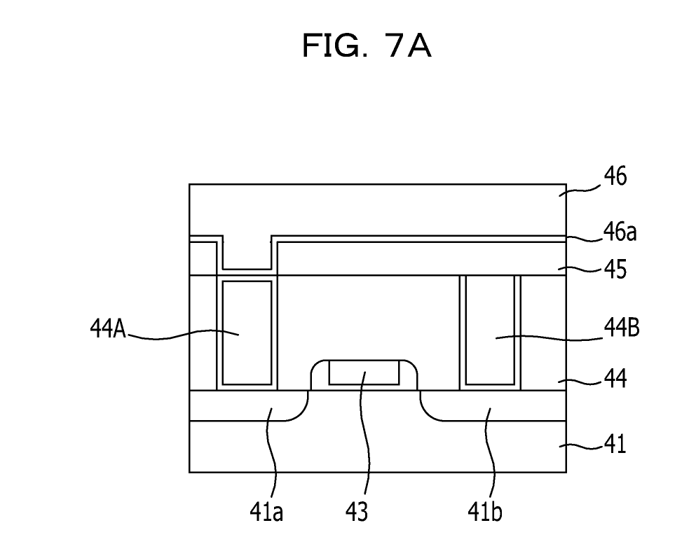

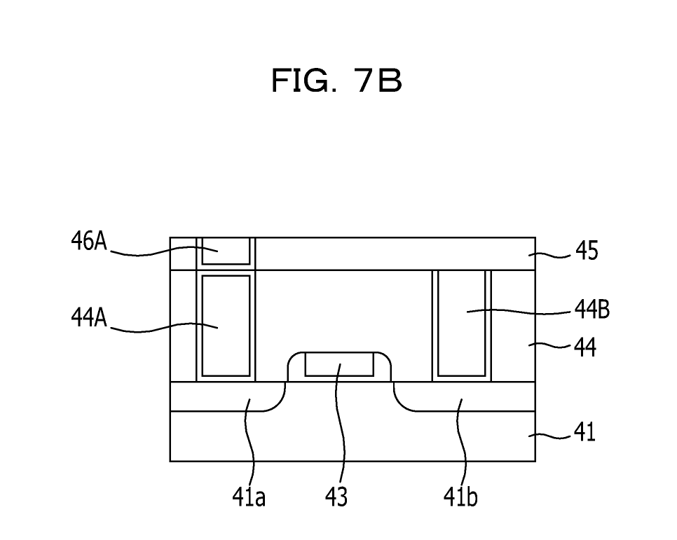

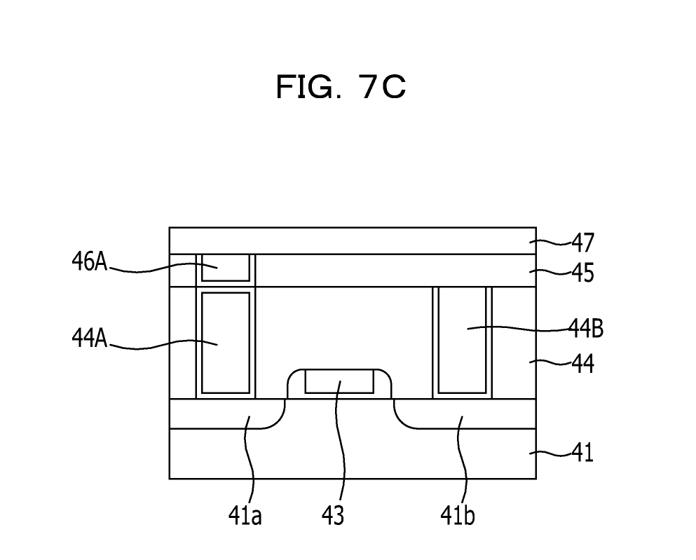

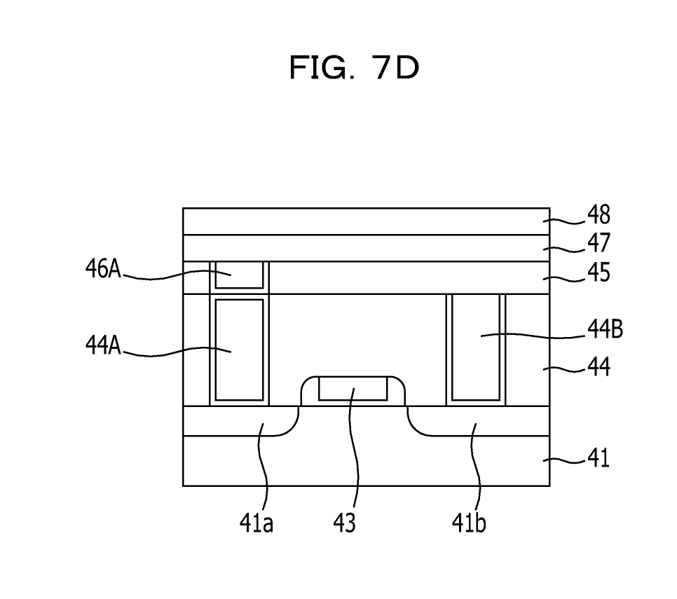

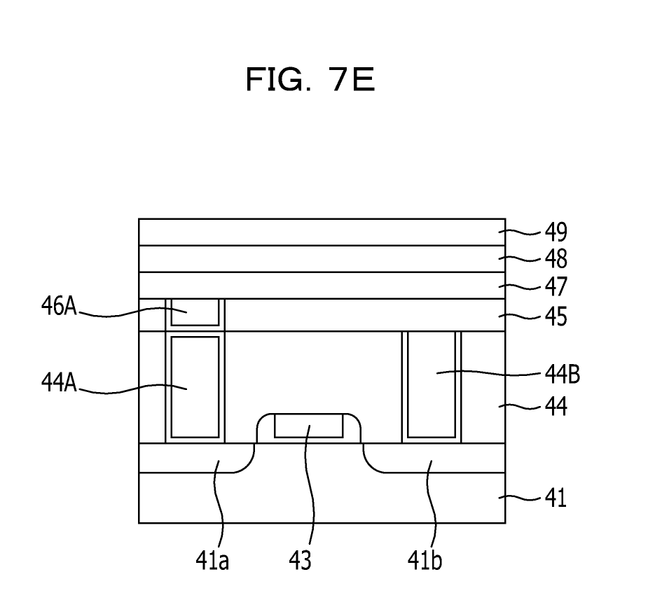

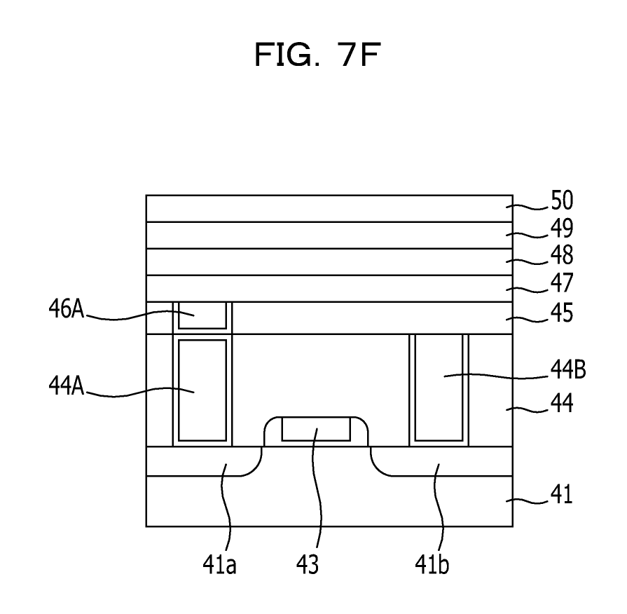

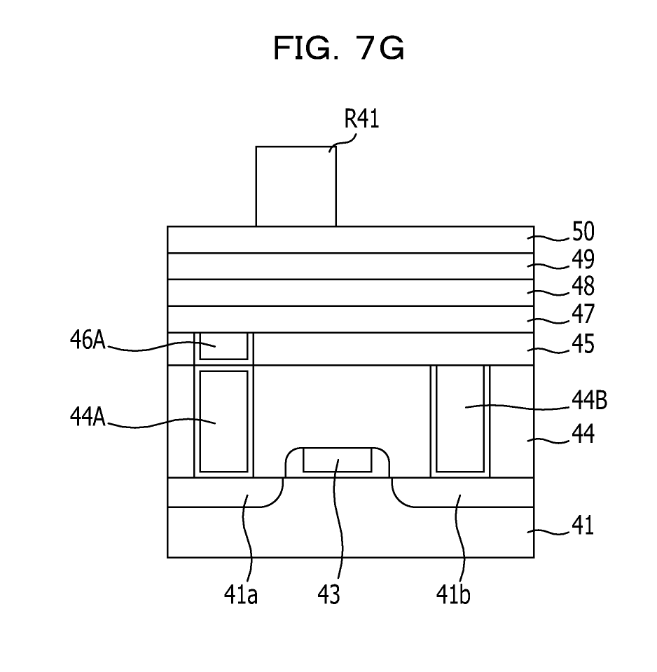

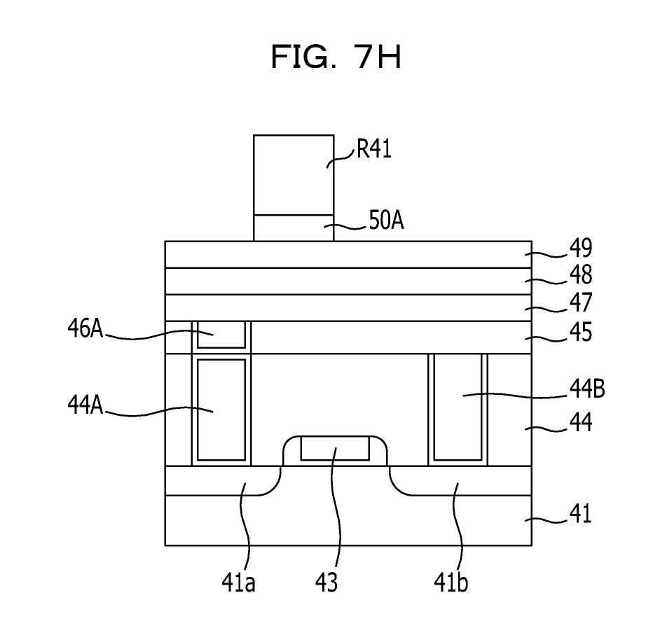

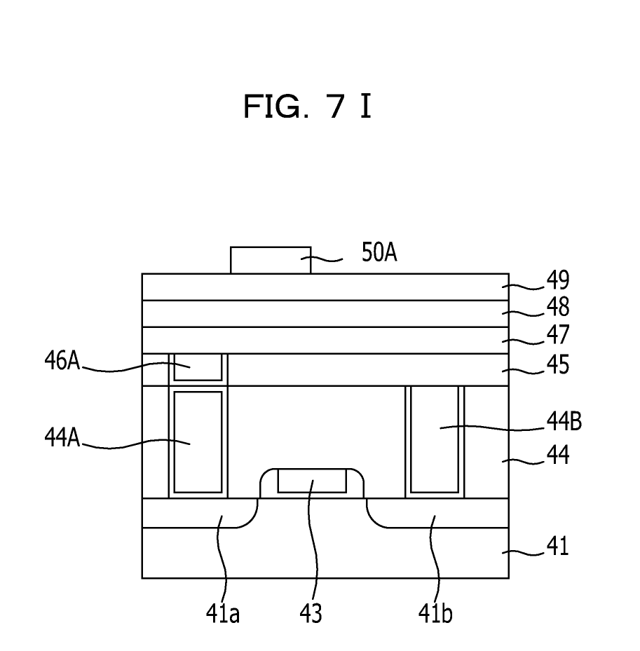

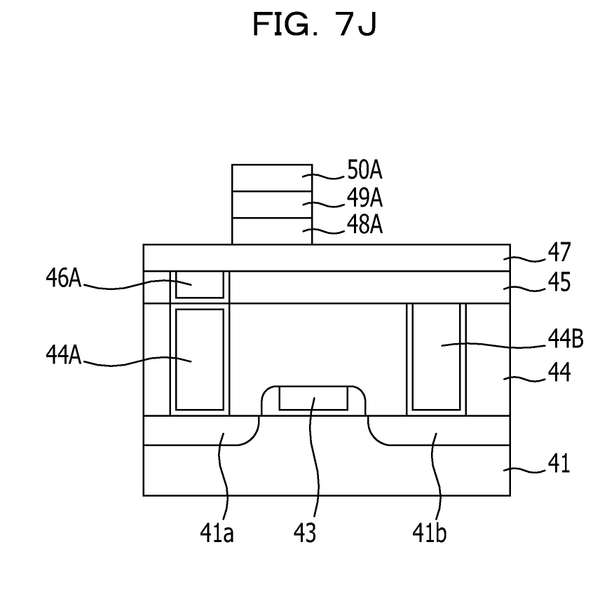

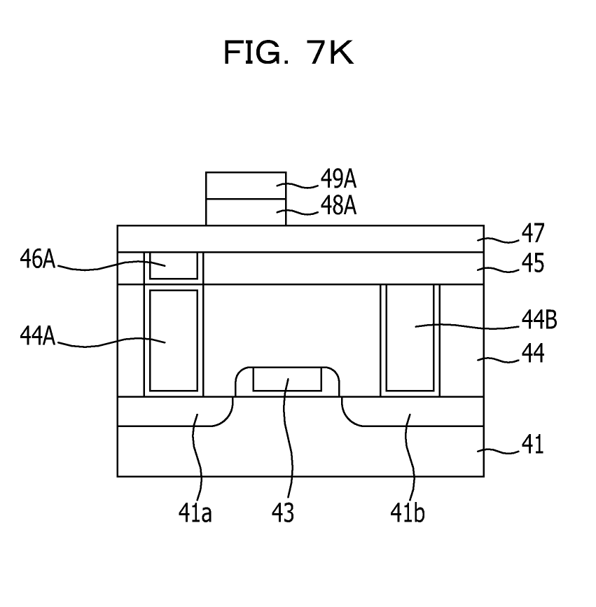

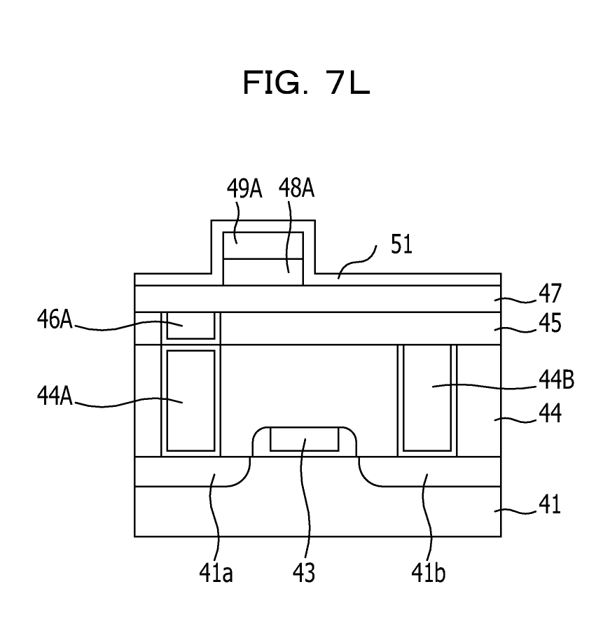

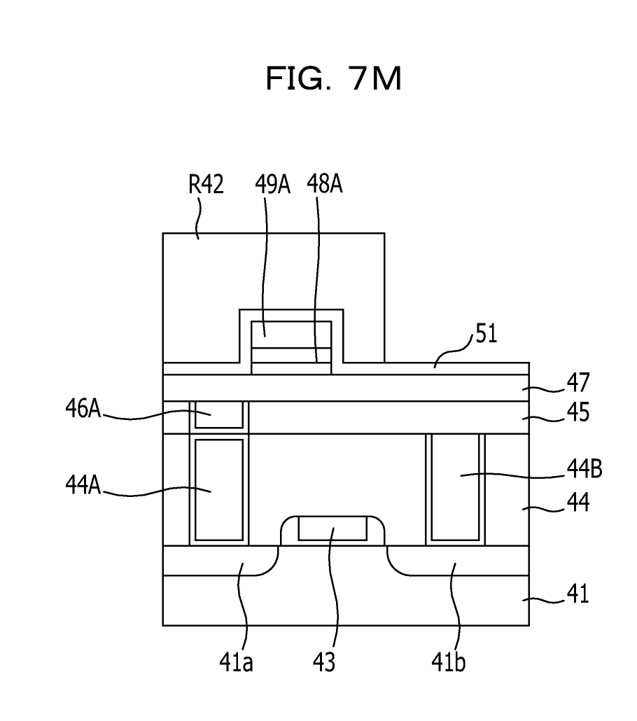

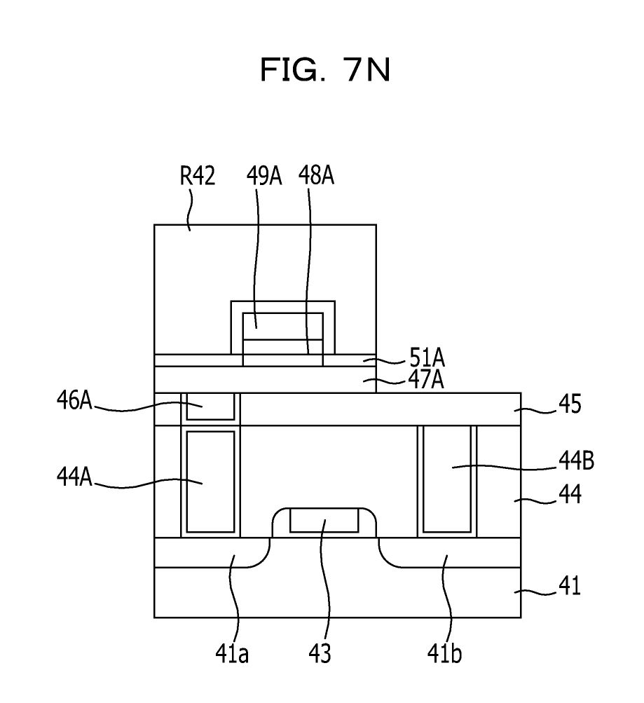

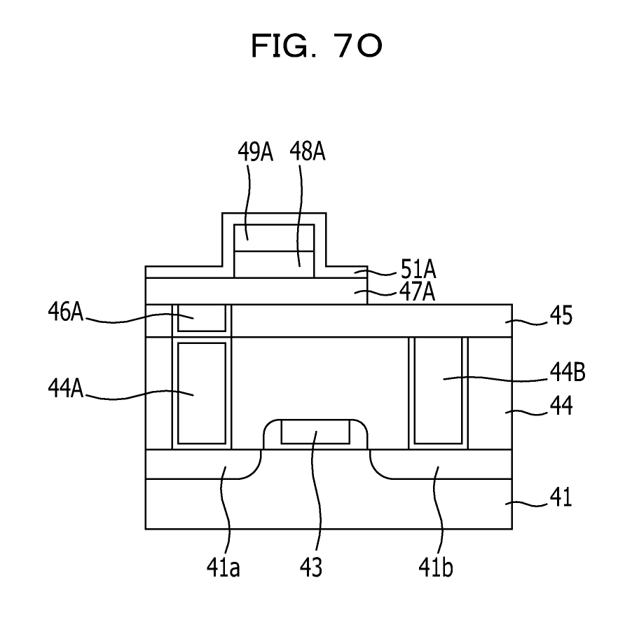

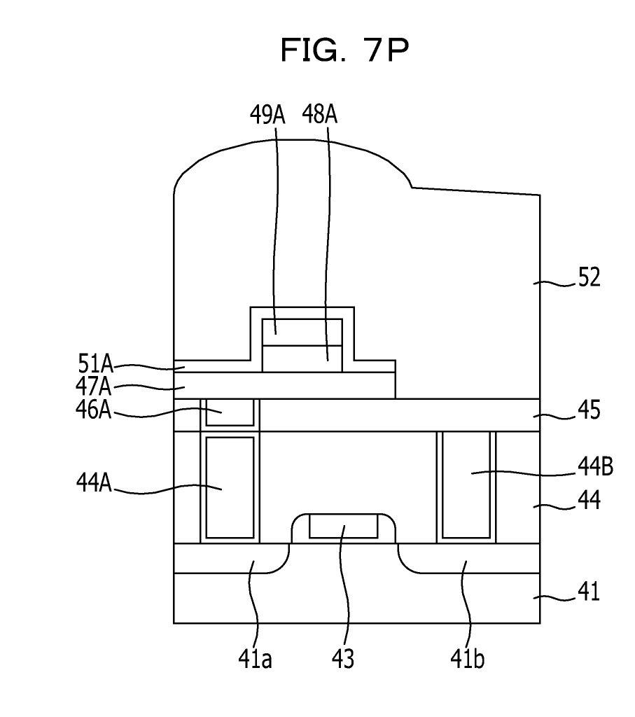

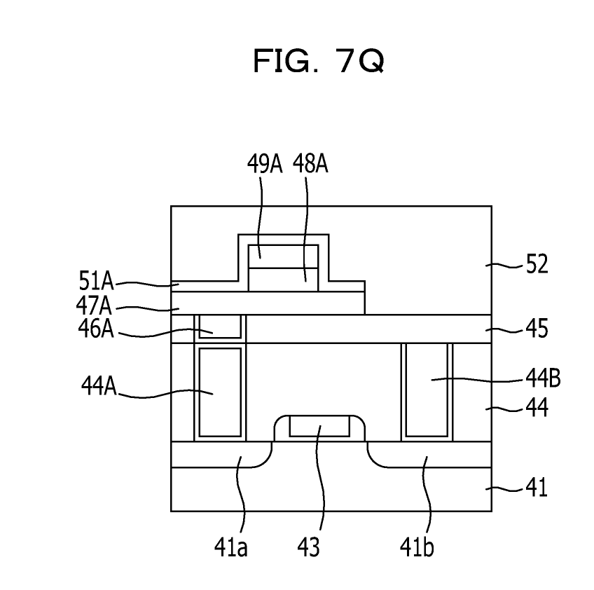

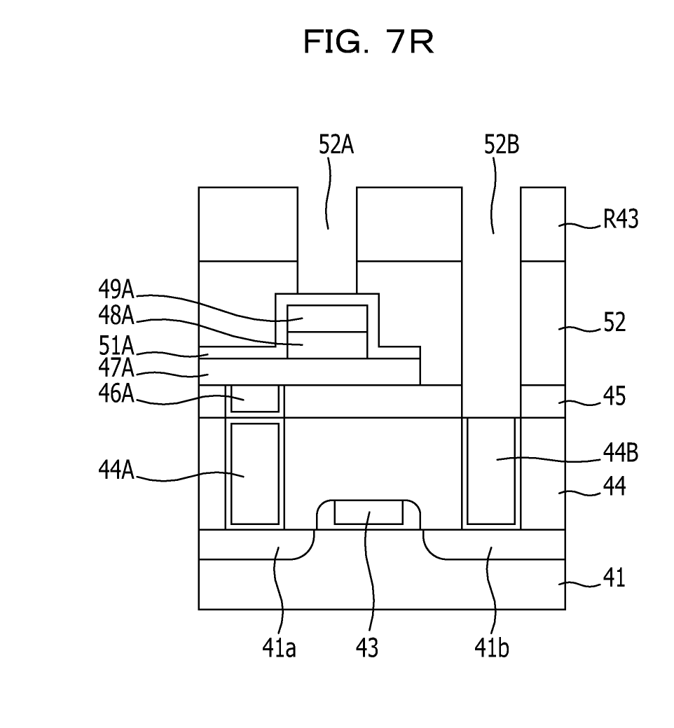

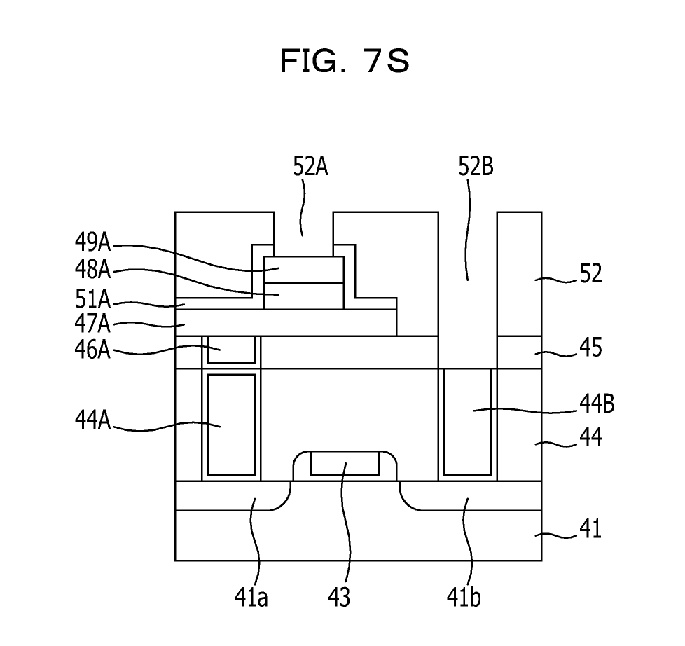

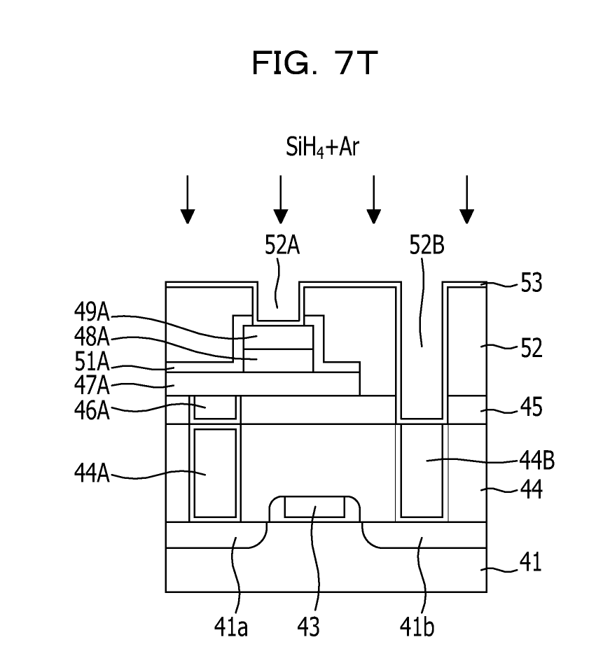

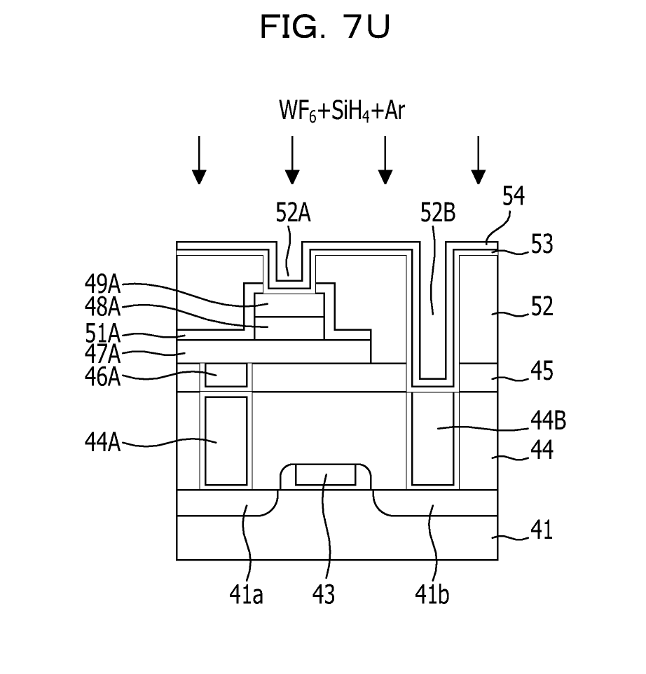

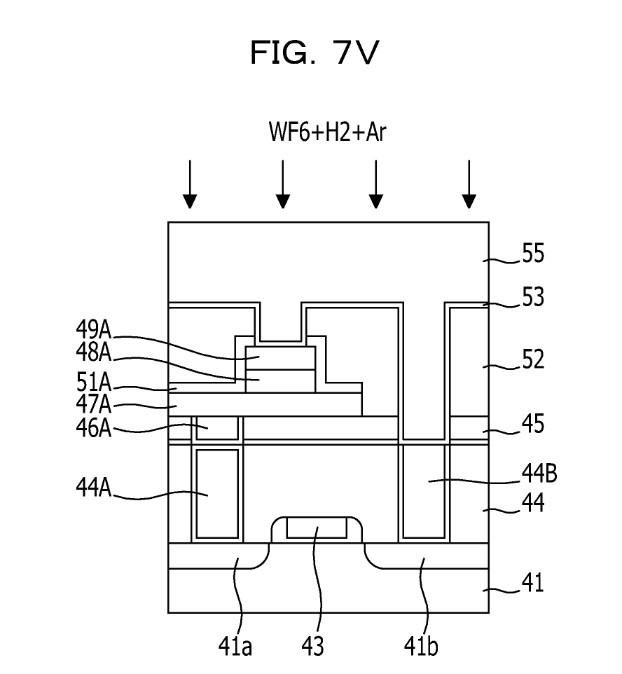

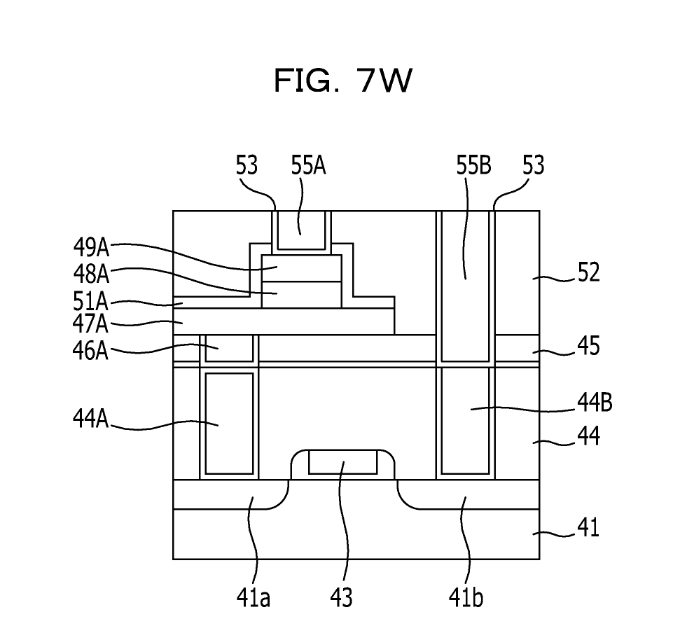

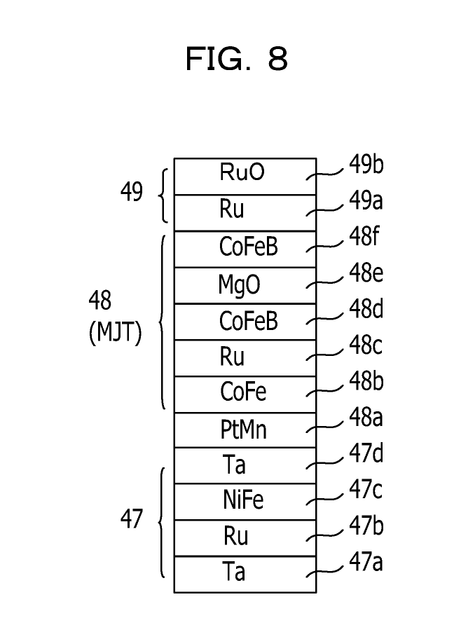

A third embodiment will now be described with reference to FIGS. 7A to 7W and FIG. 8 illustrating steps of making a magnetic random access memory (MRAM).

Referring to FIG. 7A, a gate electrode 43 is formed on a silicon substrate 41 with an gate insulating film (not illustrated in the drawing) therebetween. A source diffusion region 41a and a drain diffusion region 41b are respectively formed in the silicon substrate 41 in two regions opposing each other with a channel region directly below the gate electrode 43 therebetween.

The gate electrode 43 as well as the side wall insulating film is covered with a first interlayer insulating film 44. Via plugs 44A and 44B composed of tungsten or the like are formed in the first interlayer insulating film 44 to respectively contact the source diffusion region 41a and the drain diffusion region 41b.

A second interlayer insulating film 45 is formed on the first interlayer insulating film 44. In the state illustrated in FIG. 7A, a contact hole that exposes the via plug 44A is formed in the second interlayer insulating film 45. The contact hole is filled with a tungsten layer 46 with a barrier metal film 46a, such as Ti/TiN or Ta/TaN, interposed between the tungsten layer 46 and the via plug 44A.

In the step illustrated in FIG. 7B, a portion of the tungsten layer 46 above the second interlayer insulating film 45 is removed along with the barrier metal film 46a underneath by chemical mechanical polishing. Another via plug 46A that contacts the via plug 44A is formed in the second interlayer insulating film 45.

In the step illustrated in FIG. 7C, a lower electrode layer 47 for a magnetic tunneling junction (MTJ) structure 48 illustrated in FIG. 8 is formed on the second interlayer insulating film 45. In the step illustrated in FIG. 7D, the MTJ structure 48 corresponding to the layered structure of a desired MTJ device is formed on the lower electrode layer 47.

Referring now to FIG. 8, the lower electrode layer 47 has a structure in which, for example, a tantalum (Ta) film 47a 5 nm in thickness, a ruthenium (Ru) film 47b 50 nm in thickness, a nickel iron (NiFe) film 47c 5 nm in thickness, and a tantalum (Ta) film 47d 10 nm in thickness are sequentially deposited in that order, for example, by sputtering. An antiferromagnetic pinning layer 48a constituted by a PtMn film 15 nm in thickness, a first pinned layer 48b constituted by a cobalt iron (CoFe) film 2.5 nm in thickness, a nonmagnetic layer 48c constituted by a ruthenium (Ru) film 0.68 nm in thickness, and a second pinned layer 48d constituted by cobalt iron boron (CoFeB) film 2.2 nm in thickness are sequentially deposited on the lower electrode layer 47 by, for example, sputtering. The antiferromagnetic pinning layer 48a has a stable magnetization due to antiferromagnetic coupling and maintains constant magnetization despite the external magnetic field. The first and second pinned layers 48b and 48d are exchange-coupled through the nonmagnetic layer 48c composed of ruthenium and maintains a stable magnetization that is restricted by the magnetization of the antiferromagnetic pinning layer 48a and remains unaffected by the external magnetic field.

A magnesium oxide (MgO) film, for example, 1.16 nm in thickness is formed on the second pinned layer 48d also by sputtering or the like, and serves as a tunneling insulating film 48e. A CoFeB film having magnetization that changes in response to the external magnetic field is formed on the magnesium oxide (MgO) film 48e. The CoFeB film has a thickness of, for example, 1.5 nm, is deposited by, for example, sputtering, and serves as a free layer 48f.

A ruthenium (Ru) film 49a, for example, 10 nm in thickness and a ruthenium oxide (RuOx) film 49b, for example, 30 nm in thickness that constitute an upper electrode 49 are sequentially deposited on the free layer 48f by sputtering. Instead of the ruthenium oxide (RuOx) film 49b, an iridium oxide (IrOx) film, a strontium titanate (SrTiO₃) film, a strontium ruthenium oxide (SrRuO₃) film, or the like may be used.

Referring now to FIG. 7E, the upper electrode 49 is formed on the MTJ structure 48. Then in the step illustrated in FIG. 7F, a hard mask film 50 constituted by, for example, a Ta film with a thickness of 30 nm is formed on the upper electrode 49, typically by sputtering.

Next, as illustrated in FIG. 7G, a resist pattern R41 is formed on the hard mask film 50. Then as illustrated in FIG. 7H, the hard mask film 50 is patterned using the resist pattern R41 as a mask so as to form a hard mask pattern 50A

In the step illustrated in FIG. 7I, the resist pattern R41 is removed by, for example, ashing. In the step illustrated in FIG. 73, the upper electrode 49 and the MTJ structure 48 under the hard mask pattern 50A are patterned using the hard mask pattern 50A as a mask so as to form a MTJ element 48A supporting an upper electrode pattern 49A.

In the step illustrated in FIG. 7K, the hard mask pattern 50A is removed by, for example, wet etching. In the step illustrated in FIG. 7L, an insulating film 51 composed of silicon nitride (SiN) or the like is formed to a thickness of, for example, 10 nm on the structure illustrated in FIG. 7K.

In the step illustrated in FIG. 7M, a resist pattern R42 is formed on the structure illustrated in FIG. 7L. In the step illustrated in FIG. 7N, the insulating (SiN) film 51 and the lower electrode layer 47 underneath are patterned using the resist pattern R42 as a mask to form a lower electrode pattern 47A. As illustrated in FIG. 7O, when the resist pattern R42 is removed, the MTJ element 48A having the lower electrode pattern 47A and the upper electrode pattern 49A is formed while being covered with a SiN pattern 51A.

In the step illustrated in FIG. 7P, the structure illustrated in FIG. 7O is covered with an interlayer insulating film 52 formed by CVD using a TEOS raw material, for example. The structure is planarized by chemical mechanical polishing to obtain a structure illustrated in FIG. 7Q. The interlayer insulating film 52 is not limited to a CVD film using the TEOS raw material and may be, for example, an organic or inorganic low-dielectric-constant insulating film (a.k.a., low-k film). The method for forming the interlayer insulating film 52 is not limited to CVD. For example, a coating technique may be used to form the interlayer insulating film 52.

In the step illustrated in FIG. 7R, a contact hole 52A is formed for the MTJ element 48A and a via hole 52B is formed for the via plug 44B in the interlayer insulating film 52 using a resist pattern R43 as a mask. In the step illustrated in FIG. 7S, the upper electrode pattern 49A is exposed in the contact hole 52A.

In the step illustrated in FIG. 7T, a barrier metal film 53 constituted by a TiN film, a TaN film, or the like, is formed on the structure illustrated in FIG. 7S and exposed to a silane gas atmosphere. This corresponds to the silane gas exposure step described earlier with reference to FIG. 1A. As a result, a silicon-rich layer (not illustrated) that corresponds to the silicon-rich layer 16 illustrated in FIG. 1B is formed on the surface of the barrier metal film 53. During this process, hydrogen is either not added or added at a flow rate twice the silane gas flow rate or less to effectively suppress reduction of the ruthenium oxide (RuOx) film 49b with hydrogen.

Next, in the step illustrated in FIG. 7U corresponding to the step illustrated in FIG. 1C, WF₆ and silane gas are supplied on the structure illustrated in FIG. 7S to form a tungsten film 54 on the barrier metal film 53 on the interlayer insulating film 52 and the inner wall surfaces and bottom surfaces of the contact holes 52A and 52B by reduction of the WF₆ gas with silane. In the step illustrated in FIG. 7U also, either hydrogen is not added or if added, the hydrogen gas flow rate is limited to twice the silane gas flow rate or less.

In the step illustrated in FIG. 7V corresponding to the step illustrated in FIG. 1D, a burying tungsten film 55 is formed on the structure illustrated in FIG. 7U by a normal process of reducing the WF₆ gas with hydrogen gas. In FIG. 7V also, the burying tungsten film 55 is depicted as including the tungsten film 54.

In the step illustrated in FIG. 7W, the tungsten film 54 and the barrier metal film 53 on the interlayer insulating film 52 are removed by CMP. A tungsten plug 55A corresponding to the MTJ element 48A and a tungsten plug 55B continuous with the tungsten plug 44B are formed.

Although the detailed description is omitted here, a multilayer wiring structure is formed on the structure illustrated in FIG. 7W.

The steps illustrated in FIGS. 7T to 7V of this embodiment may also be carried out according to the recipe of FIG. 3 or 4.

In this embodiment also, an iridium oxide film, a strontium ruthenium oxide film, a strontium titanate film, or the like may be used instead of the ruthenium oxide (RuOx) film 49b included in the upper electrode 49.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. A semiconductor device comprising:
a functional element including an upper electrode composed of an electrically conductive metal oxide and being configured to store information;
an interlayer insulating film covering the functional element;
a contact hole formed in the interlayer insulating film, the contact hole including a side wall surface and a bottom and exposing an upper surface of the upper electrode at the bottom;
an electrically conductive barrier film covering the bottom and the side wall surface of the contact hole; and
a tungsten film formed on the electrically conductive barrier film, the tungsten film filling at least part of the contact hole,
wherein a layer in which silicon atoms are concentrated is formed at the interface between the tungsten film and the electrically conductive barrier film.

2. The semiconductor device according to claim 1, wherein the layer in which the silicon atoms are concentrated has a thickness of a monoatomic layer to 0.3 nm.

3. The semiconductor device according to claim 1, wherein the electrically conductive barrier film is a titanium nitride film or a tantalum nitride film.

4. The semiconductor device according to claim 1, wherein the functional element is a ferroelectric capacitor including a lower electrode and a ferroelectric film disposed on the lower electrode, and the upper electrode is disposed on the ferroelectric film.

5. The semiconductor device according to claim 1, wherein the functional element is a magnetic tunneling junction element including a lower electrode and a magnetic tunneling junction portion disposed on the lower electrode, and the upper electrode is disposed on the magnetic tunneling junction portion.

6. The semiconductor device according to claim 1, wherein the upper electrode is composed of one of iridium oxide, ruthenium oxide, strontium ruthenium oxide, and strontium titanate.

7. A method for making a semiconductor device, comprising:
a step of covering a functional element with an interlayer insulating film, the functional element including an upper electrode composed of an electrically conductive oxide and being configured to store information;
a step of forming a contact hole in the interlayer insulating film, the contact hole including a side wall surface and a bottom and exposing an upper surface of the upper electrode at the bottom;
a step of covering the bottom and the side wall surface of the contact hole with an electrically conductive barrier film;
an initialization step of supplying a silane gas and a first carrier gas to expose the electrically conductive barrier film covering the bottom and the side wall surface of the contact hole to the silane gas;
an initial tungsten deposition step of supplying a silane gas, a second carrier gas, and a tungsten source gas after the initialization step so as to deposit an initial tungsten film on the bottom and the side wall surface of the contact hole; and
a tungsten filling step of supplying a tungsten source gas and a hydrogen gas after the initial tungsten deposition step to deposit another tungsten film on the initial tungsten film and to at least partly fill the contact hole with the tungsten film,
wherein the first carrier gas and the second carrier gas each contain an inert gas, and the first carrier gas and the second carrier gas are either free of hydrogen gas or contain a hydrogen gas at a flow rate twice a silane gas flow rate or less.

8. The method according to claim 7, wherein the initialization step is continued for 53 seconds or more.

9. The method according to claim 7, wherein the initialization step is continued for 100 seconds or more.

10. The method according to claim 7, wherein the inert gas is at least one of an argon gas or a nitrogen gas.

11. The method according to claim 7, wherein, in the initialization step, a layer in which silicon atoms are concentrated and which is formed on the bottom and the side wall surface of the contact hole is formed to a thickness of a monoatomic layer to 0.3 nm.

12. The method according to claim 7, wherein the tungsten filling step includes a first stage of supplying the hydrogen gas at a first flow rate and a second stage of supplying the hydrogen gas at a second flow rate lower than the first flow rate, the second stage being performed continuously after the first stage, and
in the second stage, the flow rate of the tungsten source gas is increased from that in the first stage.

13. The method according to claim 7, wherein the initialization step further includes a step of increasing the flow rate of the silane gas.

14. The method according to claim 7, wherein the functional element is a ferroelectric capacitor including a lower electrode, a ferroelectric film disposed on the lower electrode, and the upper electrode disposed on the ferroelectric film.

15. The method according to claim 7, wherein the functional element is a magnetic tunneling junction element including a lower electrode and a magnetic tunneling junction portion disposed on the lower electrode, and
the upper electrode is disposed on the magnetic tunneling junction element.

16. The method according to claim 7, wherein the electrically conductive oxide is one of ruthenium oxide, iridium oxide, strontium ruthenium oxide, and strontium titanate.
